(19) United States
(12) Patent Application Publication
(10) Pub. No.: US 2009/0068765 A1
(43) Pub. Date: Mar. 12, 2009

(54) METHOD OF MANUFACTURING SEMICONDUCTOR DEVICE AND APPARATUS FOR MANUFACTURING SEMICONDUCTOR DEVICE

(76) Inventor: Kenichi MUROOKA, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/969,564

(22) Filed: Jan. 4, 2008

Related U.S. Application Data
(63) Continuation-in-part of application No. 11/522,397, filed on Sep. 18, 2006.

(30) Foreign Application Priority Data
Mar. 8, 2006 (JP) 2006-063268
Jan. 12, 2007 (JP) 2007-004888

(51) Int. Cl. H01L 21/02; B32B 37/14

(52) U.S. Cl. 438/5; 156/378; 257/E21.002

(57) ABSTRACT

A method of manufacturing a semiconductor device includes performing positioning between a transfer position of a pattern forming surface of a transfer original plate on which a pattern to be transferred is formed and a transferred position of a transferred surface of a transferred substrate to which the pattern is to be transferred; contacting the pattern forming surface with the transferred surface; and partly correcting the positional deviation between the transfer position of the pattern forming surface and the transferred position of the transferred surface in the in-plane direction, after the positioning is performed.

### CROSS-REFERENCE TO RELATED APPLICATIONS

This application is a continuation-in-part of U.S. patent application Ser. No. 11/522,397, with a filing data of Sep. 18, 2006. Priority of the above-mentioned application is claimed and the above-mentioned application is hereby incorporated by reference in its entirely.

### BACKGROUND OF THE INVENTION

1. Field of the Invention

The present invention relates to a method of manufacturing a semiconductor device and an apparatus for manufacturing a semiconductor device.

2. Description of the Related Art

As the integration of a semiconductor device is increased in recent years, a circuit pattern for an LSI device constituting the semiconductor device has been more and more scaled down. In the microfabrication of the circuit pattern of the LSI device, not only the critical dimension is reduced, but also the enhancement in the dimensional precision and positional precision of the circuit pattern is required. Therefore, a great load is imposed on the lithography technique for forming a pattern, which entails an increase in cost for a lithography process that accounts for most of a current mass-production cost, i.e., entails an increase in a production cost.

Conventionally, a reduction projection exposure technique using ultraviolet light is a mainstream of a lithography technique for a mass-production. However, as the wavelength of the ultraviolet light used for an exposure has been reduced, the cost for a projection optical system has rapidly been increased. In order to absorb the increase in the device cost even in a small amount, a chemically amplified high-sensitive resist is used under the pressure of necessity, and consequently, it becomes difficult in principle to reduce the edge roughness of the resist than the acid diffusion length. Therefore, the influence given to the pattern dimension cannot be neglected.

On the other hand, attention has been paid to a same size, namely one-to-one contact transfer represented by an imprint lithography as a technique for fundamentally solving the problem of the reduction projection exposure. An expensive projection optical system is unnecessary in the same size contact transfer, so that it is possible to dramatically reduce the device cost. A chemically amplified resist is also unnecessary in the same size contact transfer, so that it is possible to prevent the edge roughness of the resist.

However, the same size contact transfer involves a problem for securing the positional precision. Particularly, with the enhancement in the positional precision required for forming fine patterns, the in-plane distortion due to the deformation of the base substrate is no longer negligible. Therefore, it is inevitable to introduce some new technology. A technique for changing the height of the mask substrate has conventionally been disclosed in, for example, JP-A 2002-289560 (KOKAI) in order to eliminate the non-uniformity in the pressing pressure at the pressing surface upon the pressing in the imprint lithography.

However, the above-mentioned conventional technique aims to eliminate the non-uniformity in the pressing pressure at the pressing surface upon the pressing, and the countermeasure for the partial in-plane distortion is not recognized as a subject. In the same size contact transfer, the precision in the positioning of the transfer pattern becomes tough with the size reduction of the pattern in microfabrication, whereby it is feared that the in-plane distortion of the base pattern caused by the deformation in the plane of the base substrate or the in-plane distortion caused by the deviation of the surface of the base substrate from the flat surface has a non-negligible size.

The microfabrication of the circuit pattern of the LSI device results in increase of wiring resistance because of a smaller wire cross-section and increase of inter-wire capacitance because of a narrower distance between adjacent wires. For this reason, the signal delay time which is proportional to the product of the wiring resistance and the capacitance increases, thereby inhibiting high-speed circuit operation.

A method using a multiple wiring layer has been used to decrease the signal delay. Unfortunately, as a total number of wiring layers increases, a number of lithography processes increases. Because lithography processes account for most of current mass-production costs, a multiple wiring layer can be a factor of increasing manufacturing costs. Moreover, if the wiring resistance decreases under conditions that the voltage at the electric source is constant, the current increases so that a larger amount of power is consumed. The multiple wiring can cause a need of reducing the power consumption.

An optical fiber wiring technology that uses light instead of electricity for transferring signals has been focused as a technology to fundamentally solve the above wiring problems. The optical fiber wiring uses optical waveguides instead of electric wires for transferring signals. A speed of signals transmitted through an optical waveguide depends only on a refractive index of the optical waveguide and reaches about a half to about a one-third of the light velocity in vacuum in a normal case. Therefore, the optical fiber wiring is promising as a new technology replaced with the electric wiring specifically in a field of long-distance communications. For example, JP-A 2006-23777 (KOKAI) discloses an optoelectronic integrated circuit (IC) using the optical fiber wiring.

In the optoelectronic IC, an electric element and an optical element are formed on a single substrate. To form the single substrate, because the optical element, such as a light emission element and a light receiving element for use together with the optical waveguide, is made of a III-V group semiconductor, which belongs to a group different from that to which silicon, i.e., a typical semiconductor element, belongs, a process of bonding different-type substrates is required. The process of bonding the optical elements requires high positional-alignment precision enough for about one-eighth value or shorter of the wavelength of the light to be used. Such a high precision is difficult for the conventional bonding technique. However, the difficulty is not recognized as an issue in, for example, JP-A 2006-23777 (KOKAI).

The process of bonding different-type substrates is required to produce the optoelectronic IC. However, it is difficult to achieve the high positional-alignment precision at any portions between the optical elements. It is feared that the in-plane distortion of the base pattern caused by the deformation in the plane of the base substrate or the in-plane distortion caused by the deviation of the surface of the base substrate from the flat surface has a non-negligible size. Difference in size makes the bonding process more difficult. A substrate having a 12-inch diameter has been nearly recognized as a standard silicon substrate, while a substrate having a smaller 4-inch diameter has been widely-used as the III-V group semiconductor substrate. Therefore, it is difficult to form the optoelectronic IC on the silicon wafer using a simple one-to-one bonding process. In other words, the positional-alignment technique satisfying the high precision required for forming the optoelectronic IC has not established yet.

### SUMMARY OF THE INVENTION

According to one aspect of the present invention, a method of manufacturing a semiconductor device, the method includes performing positioning between a transfer position of a pattern forming surface of a transfer original plate on which a pattern to be transferred is formed and a transferred position of a transferred surface of a transferred substrate to which the pattern is to be transferred; contacting the pattern forming surface with the transferred surface; and partly correcting the positional deviation between the transfer position of the pattern forming surface and the transferred position of the transferred surface in the in-plane direction, after the positioning is performed.

According to another aspect of the present invention, an apparatus for manufacturing a semiconductor device, the apparatus includes a press-contact unit that presses a pattern forming surface of a transfer original plate on which a pattern to be transferred is formed and a transferred surface of a transferred substrate to which a resist film is to be applied and the pattern is to be transferred, thereby bringing the pattern forming surface and the transferred surface into contact with each other; a positioning unit that positions the transfer position of the pattern forming surface and the transferred position of the transferred surface; a positional deviation correcting unit that partly corrects the positional deviation in the in-plane direction between the transfer position of the pattern forming surface and the transferred position of the transferred surface at the contact surface of the pattern forming surface and the transferred surface; and a light source that irradiates light to expose the resist film on the transferred substrate.

According to still another aspect of the present invention, a method of manufacturing a semiconductor device including bonding of a first substrate and a second substrate, the method includes holding a state of facing one surface of the first substrate and one surface of the second substrate and being close to each other; aligning a position between the one surface of the first substrate and the one surface of the second substrate with respect to an in-plane direction; measuring a distribution of positional deviations between the one surface of the first substrate and the one surface of the second substrate with respect to the in-plane direction after aligning the position; bonding the one surface of the first substrate and the one surface of the second substrate by pressing from an opposite surface side of the first substrate; and partly correcting the positional deviations between the first surface and the second surface with respect to the in-plane direction based on the distribution of positional deviations while pressing from the opposite surface side of the first substrate.

According to still another aspect of the present invention, an apparatus for manufacturing a semiconductor device by bonding a first substrate and a second substrate, the apparatus includes a holding unit that holds a state of facing one surface of the first substrate and one surface of the second substrate and being close to each other; an aligning unit that aligns a position between the one surface of the first substrate and the one surface of the second substrate with respect to an in-plane direction while facing the one surface of the first substrate and the one surface of the second substrate; a positional-deviation distribution measuring unit that measures a distribution of positional deviations between the one surface of the first substrate and the one surface of the second substrate with respect to the in-plane direction after aligning the position; a press-contact unit that bonds the one surface of the first substrate and the one surface of the second substrate by pressing from the opposite surface side of the first substrate; and a correcting unit that partly corrects the positional deviations between the one surface of the first substrate and the one surface of the second substrate with respect to the in-plane direction based on the distribution of positional deviations, while pressing from the opposite surface side of the first substrate by the press-contact unit.

### BRIEF DESCRIPTION OF THE DRAWINGS

FIG. 1 is a schematic diagram of a pattern transfer apparatus according to a first embodiment of the present invention;

FIG. 2A is a schematic sectional diagram of a wafer for explaining a principle of correction used in the pattern transfer apparatus;

FIG. 2B is an enlarged schematic diagram of an area A shown in FIG. 2A;

FIG. 3A is a schematic sectional diagram of a mask substrate and the wafer for explaining a principle of correction used in the pattern transfer apparatus;

FIG. 3B is an enlarged schematic diagram of an area B shown in FIG. 3A;

FIG. 4 is a flowchart of a pattern transfer process according to the first embodiment;

FIG. 5 is a flowchart of a pattern transfer process according to a second embodiment of the present invention;

FIGS. 6A and 6B are a flowchart of a pattern transfer process according to a third embodiment of the present invention;

FIG. 7 is a schematic diagram of a pattern transfer apparatus according to a fourth embodiment of the present invention;

FIG. 8 is an equivalent circuit diagram of a mask substrate of the pattern transfer apparatus according to the fourth embodiment;

FIG. 9 is a flowchart of a pattern transfer process according to the fourth embodiment;

FIG. 10 is a flowchart of a pattern transfer process according to a fifth embodiment of the present invention;

FIGS. 11A and 11B are flowcharts of a pattern transfer process according to a sixth embodiment of the present invention;

FIG. 12 is a schematic diagram of an apparatus for manufacturing a semiconductor device according to a seventh embodiment of the present invention;

FIG. 13 is a schematic diagram of another apparatus for manufacturing a semiconductor device according to the seventh embodiment;

FIG. 14A is a schematic sectional diagram of wafers for explaining a principle of correction used in the substrate-bonding devices;

FIG. 14B is an enlarged schematic diagram of an area B shown in FIG. 14A;

FIG. 15A is a flowchart of a substrate bonding process according to the seventh embodiment;

FIG. 15B is a flowchart of another substrate bonding process according to the seventh embodiment;

FIG. 16A is a perspective diagram of a height adjusting unit shown in FIG. 12;

FIG. 16B is an enlarged diagram of an area D shown in FIG. 16A;

FIG. 16C is a perspective diagram of a height adjusting unit shown in FIG. 13; and

FIGS. 17A to 19D are cross-sectional diagrams for explaining a method of manufacturing a semiconductor device according to an eighth embodiment of the present invention.

### DETAILED DESCRIPTION OF THE INVENTION

Exemplary embodiments of the present invention are described in detail below with reference to the accompanying drawings.

Exemplary embodiments of a pattern transfer method and a pattern transfer apparatus in manufacturing the semiconductor device are described in detailed in first to sixth embodiments of the present invention.

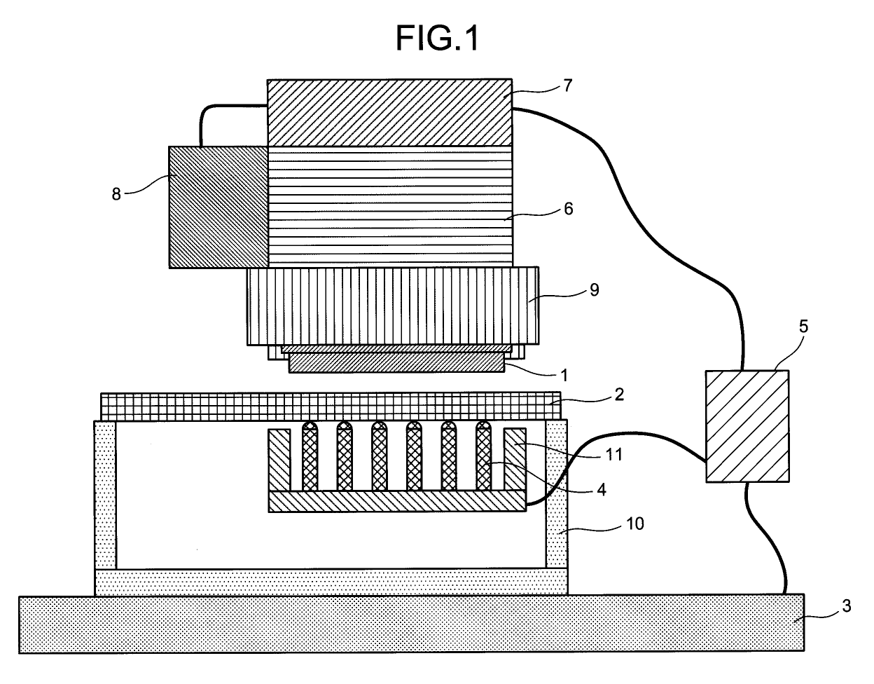

FIG. 1 is a schematic diagram of a pattern transfer apparatus according to a first embodiment of the present invention. This pattern transfer apparatus is for realizing a same size contact transfer by a pattern transfer method according to an embodiment of the present invention. The pattern transfer apparatus includes a mask substrate 1, a wafer stage 3, a height adjusting unit 4, a control unit 5, a positional-deviation distribution measuring unit 6, an operation unit 7, a resist-curing light irradiating unit 8, a press-contact unit 9, a wafer chuck 10, and a storing unit 11.

In the pattern transfer apparatus according to the first embodiment, the mask substrate 1, which is an original plate, is arranged so as to be opposite to a wafer 2, which is a substrate to which a pattern is to be transferred, as held at the press-contact unit 9. The wafer 2 is held at the wafer chuck 10 so as to be movable in the in-plane direction of the wafer stage 3 thereon. The height adjusting unit 4 that is arranged in a lattice and can partly adjust the height of the wafer 2 is disposed between the wafer 2 held at the wafer chuck 10 and the wafer stage 3. The height adjusting unit 4 is housed in the storing unit 11.

The operation of the wafer stage 3 and the operation of the height adjusting unit 4 are controlled by the control unit 5. The positional-deviation distribution measuring unit 6 measures the relative positional deviation between the pattern on the mask substrate and the pattern on the wafer with the mask substrate 1 brought into pressure contact with the wafer 2 by the press-contact unit 9. The result of this measurement is converted into a control signal of the height adjusting units 4 by the operation unit 7, and transmitted to the control unit 5. The resist-curing light irradiating unit 8 irradiates ultraviolet light, which is necessary for curing the resist, to the resist on the wafer 2 through the mask substrate 1 based upon the signal from the control unit 5 and the operation unit 7, after the positioning of the mask substrate 1 and the wafer 2 is completed.

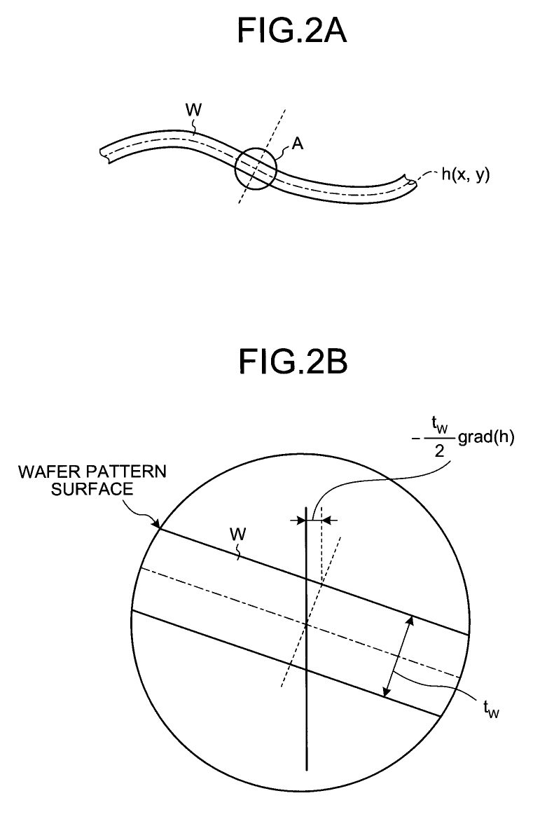

In order to explain that the distortion of the wafer 2 in the in-plane direction can be corrected by the pattern transfer apparatus having the structure shown in FIG. 1, the influence given to the positioning precision by the deformation of the substrate in the height direction will firstly be explained with reference to FIGS. 2A and 2B. FIG. 2A is a schematic sectional diagram of a wafer W for explaining the principle of the correction used in the pattern transfer apparatus according to this embodiment. FIG. 2B is an enlarged schematic diagram of the area A shown in FIG. 2A.

When the wafer is deformed in the height direction (in the direction of the thickness of the wafer), the distortion energy in the volume deformation is extremely large, so that the deformation in which the volume is constant generally occurs. Therefore, the central surface of the wafer in the thickness direction (in the height direction) becomes a neutral surface. On this central surface, the displacement in the lateral direction (in the in-plane direction of the wafer) is not produced before and after the deformation. Therefore, the displacement in the lateral direction produced between the neutral surface and the pattern surface provides a positional deviation amount.

Here, the shape of the neutral surface is described as h (x, y) using the coordinates (x, y) in the lateral direction. In this case, the positional deviation amount under the condition where h is not so large is given as −t_{W}/2*grad(h) that is obtained by multiplying the slope of h (x, y) by a half of the thickness t_{W} of the wafer and inversing the sign as shown in FIG. 2B. One example will be given as follows. Supposing that there is a wafer having a thickness of 720 μm and the deformation amount per 1 mm in the height in the lateral direction is 100 nm, the positional deviation amount of 36 nm is produced in this case.

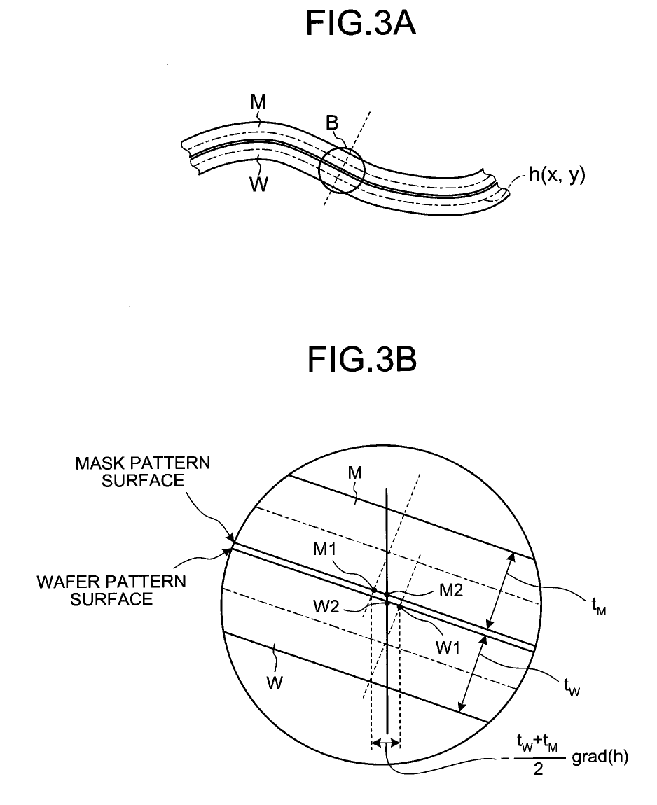

FIG. 3A is a schematic sectional diagram of the mask substrate M and the wafer W for explaining the principle of the correction in the pattern transfer apparatus according to the embodiment. FIG. 3B is an enlarged schematic diagram of an area B shown in FIG. 3A. Since the mask substrate, which is an original plate, is pressed against the wafer which is a substrate to be transferred in the same size contact transfer, the surface shape of the mask substrate goes along the surface shape of the wafer. Further, as for the mask substrate, the central surface in the thickness direction becomes a neutral surface like the above-mentioned case.

As shown in FIG. 3B, the positions where the mask substrate M and the wafer W are overlapped with each other with the wafer W being flat are defined as M1 and W1. Specifically, the transfer position on the mask pattern of the mask substrate M on the design is the position M1. The transferred position on the wafer pattern of the wafer W on the design is the position W1.

On the other hand, the position at the actual transfer on the mask pattern of the mask substrate M is the position M2. The position at the actual transfer on the wafer pattern of the wafer W is the position W2.

Accordingly, from the viewpoint of the original design, the pattern transfer is to be carried out with the position M1 on the mask pattern of the mask substrate M and the position W1 on the wafer pattern of the wafer W overlapped with each other. However, the pattern transfer is actually carried out with the position M2 on the mask pattern of the mask substrate M and the position W2 on the wafer pattern on the wafer W overlapped with each other.

Therefore, the positional deviation amount upon the pattern transfer obtained by putting together the deformation of the pattern of the wafer and the deformation of the pattern of the mask substrate is given as (t_{W}+t_{M})/2*grad(h), supposing that the thickness of the mask substrate is defined as t_{M}. One example will be given as follows. Supposing that the thickness of the wafer is 720 μm, the thickness of the mask substrate is 200 μm, and the deformation amount in the height direction is 100 nm per 1 mm in the lateral direction, the positional deviation amount of 46 nm is produced in this case.

Accordingly, the height adjusting unit is designed so as to be capable of producing a small displacement of about ±1 μm, whereby the correction of the partial positional deviation of about several tens nm in the transfer region is made possible. In general, the allowable value of the positional deviation amount is not more than a third of the critical dimension. Therefore, in the generation in which the critical dimension is not more than 45 nm, it is sufficient that the positional correction to the above-mentioned degree is made possible.

In the same size contact transfer, the mask substrate is pressed against the wafer. Therefore, the height adjusting unit 4 only has force for pushing up the wafer, so that the height adjusting unit 4 can be manufactured with simple structure and reduced cost. On the other hand, in a lithography in which the mask substrate is not pressed against the wafer, the height adjusting unit at the back surface of the wafer is required to provide not only a pushing operation but also a pulling operation when there is a need to form a concave surface. Therefore, some idea is demanded such as forming an imperceptible vacuum chuck.

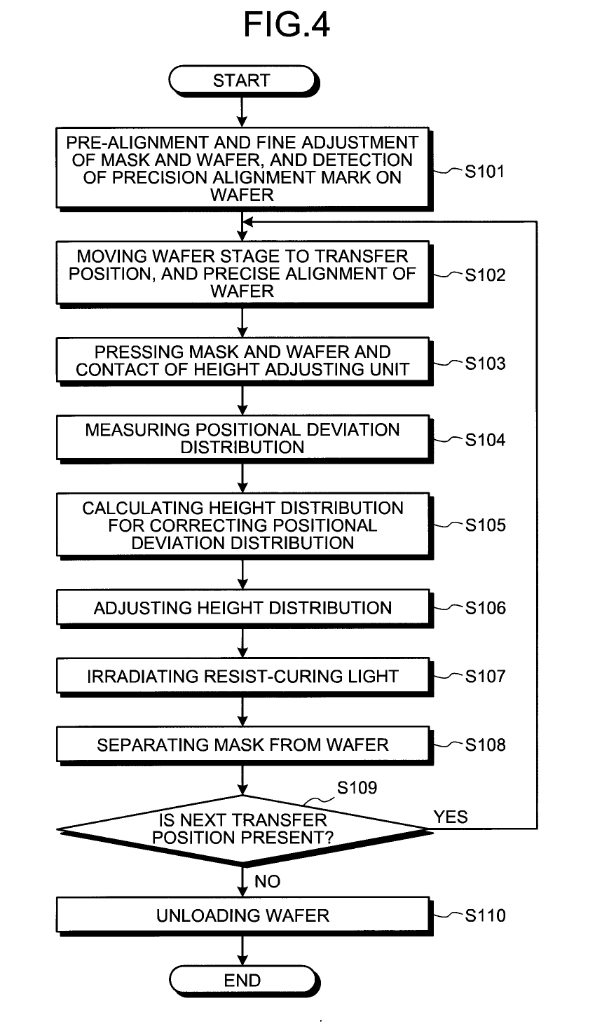

Subsequently, the actual pattern transfer method using the transfer apparatus according to the present embodiment will be explained with reference to FIG. 4. FIG. 4 is a flowchart of a pattern transfer process according to the present embodiment. Firstly, a pattern for detecting the positional deviation is formed beforehand on the mask substrate 1, which is an original plate, with the circuit pattern. It is to be noted that a part of the circuit pattern can be used for the detection of the positional deviation.

The peripheral support frame of the mask substrate 1 is made of, for example, a quartz glass having a thickness of 6.1 mm, and a pattern forming area is made of, for example, a quartz glass having a thickness of 200 μm. The wafer 2, which is a substrate to which a pattern is to be transferred, is, for example, a silicon wafer having a thickness of 720 μm. A base pattern is formed beforehand on the wafer 2, and ultraviolet curing type resist is applied thereon. The base pattern here includes the pattern for the detection of the positional deviation with the circuit pattern. It is to be noted that a part of the circuit pattern can also be used for the detection of the positional deviation.

The prepared mask substrate 1 is subjected to a rough adjustment (pre-alignment) of the position in the horizontal direction and the rotation in the horizontal plane by a pre-alignment mechanism (not shown) (step S101), and then, fixed to the mask substrate chuck at the press-contact unit 9. Then, a fine adjustment in the position in the horizontal direction and the rotation in the rotating direction is performed by using a reference mark on the wafer stage 3 (step S101).

The wafer 2 having the resist applied thereon is also subjected to a rough adjustment (pre-alignment) in the position in the horizontal direction and the rotation in the horizontal plane with a notch defined as a reference by a pre-alignment mechanism (not shown), like the mask substrate (step S101), and then, fixed to the wafer chuck 10 on the wafer stage 3. The wafer 2 is fixed to the wafer chuck 10 by utilizing the portion of the periphery of the wafer 2 where the pattern is not formed.

Subsequently, the precision alignment mark on the wafer 2 is detected, whereby the fine adjustment of the position of the wafer in the horizontal direction and the direction of rotation is performed (step S101). By detecting the precision alignment mark on the wafer 2, the positional coordinates of the base pattern on the wafer is recorded as a value to the wafer stage coordinates at this stage to form a map centered at the base pattern. This map is used as the value of the center coordinates upon the transfer.

The height adjusting unit 4 includes piezoelectric elements made of lead zirconate titanate (PZT) arranged in a lattice at an interval of 1 mm. 875 piezoelectric elements (35×25) in total are stored in the storing unit 11 so as to correspond to the shot (transfer) size of 32 mm×22 mm corresponding to the area where the pattern is formed on the wafer 2 with one transfer.

The movable region of each of the piezoelectric elements in the height direction (the thickness direction of the wafer 2 upon the transfer process) can be, for example, ±1 μm. The height adjusting unit 4 applies predetermined voltage to each of the piezoelectric elements in accordance with the signal from the control unit 5, and the height of each of the piezoelectric elements is adjusted, to thereby form a desired height distribution. Further, the overall of the storing unit 11 is movable in the vertical direction. With this configuration, when the transfer process is not performed, in particular, when the wafer 2 is moved to the next transfer region by the operation of the wafer stage 3, the height adjusting unit 4 can be withdrawn from the back surface of the wafer 2 by the movement of the whole storing unit 11.

Then, at the stage where the mask substrate 1 and the wafer 2 are placed in a predetermined state before the above mentioned pattern transfer, the wafer stage 3 is moved to the position of the center coordinates of the first shot (transfer) of the wafer 2 to perform a precise alignment of the wafer 2 (step S102), like the normal pattern transfer apparatus. Specifically, positioning is performed between the center coordinates of the first shot (transfer) of the wafer 2 and the center coordinates of the mask substrate 1. Subsequently, the press-contact unit 9 and the storing unit 11 are driven to press the mask substrate 1 against the wafer 2 and bring the height adjusting unit 4 into contact with the back surface of the wafer 2 (the surface of the wafer 2 opposite to the mask substrate 1) (step S103).

With this state, the positional deviation amount between the positional deviation detecting pattern on the mask substrate 1 and the positional deviation detecting pattern on the wafer 2 are optically measured at predetermined position using the positional-deviation distribution measuring unit 6, whereby the positional deviation distribution is measured (step S104). Supposing that the result of the measurement is defined as u(x, y) where u is a two-dimensional vector amount, the positional deviation amount u(x, y) can be cancelled according to the above-mentioned principle, if h=2/(t_{W}+t_{M})∫udl by using a line integral from the obtained u(x, y). Since the u(x, y) is actually not a continuous value but a discrete value, the integration is approximated with the sum, and the map h1 of the approximate value of h is obtained at the operation unit 7.

The position of the positional deviation detecting pattern does not always agree with the lattice position of the height adjusting unit 4. Therefore, the operation unit 7 makes an approximate polynomial to the map h1 of the approximate value to obtain each coefficient of the polynomial by the least squares method. The obtained coefficient of the polynomial is sent to the control unit 5 as data.

The control unit 5 obtains the height distribution information for correcting the positional deviation distribution by using the coefficient of the polynomial received from the operation unit 7, and calculates the correction height distribution information h2 that should be given to each lattice point of the height adjusting unit 4 (step S105). Then, the control unit 5 converts the calculated correction height distribution information h2 into the voltage that should be applied to each piezoelectric element of the height adjusting unit 4, and applies the voltage to the piezoelectric element to drive the same for adjusting the height distribution in the plane at the transfer position (step S106). The positional deviation between the mask substrate 1 and the wafer 2 can be cancelled by this height adjustment.

Next, the control unit 5 confirms the completion of the process for adjusting the height distribution in the plane at the transfer position, and then, transmits to the resist-curing light irradiating unit 8 an instruction signal for the light irradiation for the resist curing. The resist-curing light irradiating unit 8 irradiates ultraviolet light for the resist curing from the back surface of the mask substrate 1 in accordance with the instruction signal from the control unit 5, thereby transferring the resist pattern having the same shape of the pattern on the mask substrate 1 on the wafer 2 (step S107).

According to need, the positional deviation distribution can be measured again before the irradiation of the ultraviolet light for confirming whether the positional deviation is cancelled or not. With this operation, a transfer with more reliability can be performed. Further, the fine adjustment in the height can be performed again in accordance with the result of the re-measurement of the positional deviation distribution. This can more surely cancel the positional deviation, so that a transfer having more reliability can be performed. A feedback loop can be provided between the measurement of the positional deviation distribution and the height adjustment.

After the pattern is transferred by the irradiation of the ultraviolet light, the press-contact unit 9 and the storing unit 11 are separated from the wafer 2 (step S108). Then, the control unit 5 determines whether the next transfer position is present or not (step S109). When the next transfer position is present (Yes at step S109), the process control returns to step S102 so as to drive the wafer stage 3 to move the same to the center coordinates of the next shot (transfer). Then, the transfer process is repeated by the same process.

On the other hand, when the next transfer position is not present (No at step S109), i.e., when all the desired shots (transfers) on the wafer 2 are completed, the press-contact unit 9 and the storing unit 11 are again separated from the wafer 2. After they are sufficiently separated, the wafer 2 on which the pattern has already been transferred is unloaded from the wafer chuck 10 (step S110), whereby a series of transfer process of the wafer 2 is completed. After that, the transfer to the next wafer 2 can be performed by the same process.

The aforementioned series of transfer process is executed using the pattern transfer apparatus according to the present embodiment, whereby a high-quality pattern transfer having very small positional deviation distribution is made possible in which the partial distortion of the wafer 2 in the in-plane direction at the transfer position is corrected and the positioning precision between the mask substrate 1 and the wafer 2 is remarkably enhanced.

In a second embodiment of the present invention, another pattern transfer method using the pattern transfer apparatus according to the above-mentioned first embodiment will be explained. It is to be noted that, since the pattern transfer apparatus according to this embodiment is the same as that in the first embodiment, FIG. 1 and the above-mentioned explanation are referred to, and the detailed explanation thereof is not repeated.

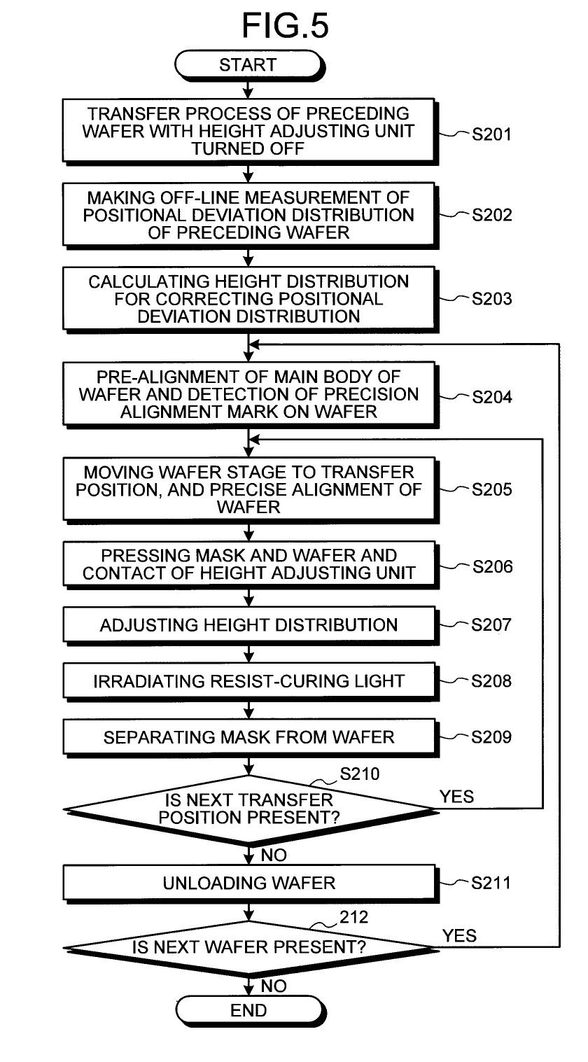

This embodiment explains the pattern transfer method in which the reproducibility in the positional deviation distribution of the wafer is high, such as plural wafers manufactured by, for example, the same lot through the same process. When the reproducibility in the positional deviation distribution is high, and the measurement of the positional deviation distribution for each wafer or the measurement of the positional deviation distribution for each shot in each wafer is unnecessary, the following simple method can be employed. This will be explained hereinafter with reference to FIG. 5. FIG. 5 is a flowchart of a pattern transfer process according to this embodiment.

Firstly, a pattern transfer is performed to a dummy wafer (hereinafter referred to as preceding wafer 2a) for measuring the positional deviation distribution and the positional deviation distribution at the shot (transfer) in the wafer. The normal pattern transfer to the preceding wafer 2a is carried out with the height adjusting unit 4 turned off, i.e., with the whole of the height adjusting unit 4 not displaced (step S201). In this pattern transfer, the above-mentioned steps S101 to S103 are executed as the preliminary process.

Next, the preceding wafer 2a to which the pattern has been transferred is unloaded from the pattern transfer apparatus, and the positional deviation distribution u(x, y) is measured by using the off-line positional deviation measuring device (step S202). It is to be noted that the off-line measuring function can be provided to the positional-deviation distribution measuring unit 6 of the pattern transfer apparatus for measuring the positional deviation distribution. Further, the obtained positional deviation distribution is input to the operation unit 7, whereby the map h1 of the approximate value is obtained by the same manner as in the first embodiment.

Subsequently, the operation unit 7 makes an approximate polynomial to the map h1 of the approximate value to obtain each coefficient of the polynomial by the same manner as in the first embodiment. The obtained coefficient of the polynomial is sent to the control unit 5 as data. The control unit 5 corrects the height distribution information for correcting the positional deviation distribution using the coefficient of the polynomial received from the operation unit 7, thereby calculating the correcting height distribution information h2 that should be given to each lattice point of the height adjusting unit 4 (step S203).

Next, the pattern transfer to the main body wafer (hereinafter referred to as wafer 2), which is to be a product, is carried out. Since the rough adjustment (pre-alignment) and fine adjustment of the mask substrate 1 has already been completed as the preliminary process, the rough adjustment (pre-alignment) and fine adjustment for the wafer 2 having the resist applied thereon is executed. Specifically, the rough adjustment (pre-alignment) of the position in the horizontal direction and the rotation in the horizontal plane is carried out with the notch defined as a reference by using a pre-alignment mechanism (not shown) (step S204), like the case of the mask substrate 1, and then, the wafer 2 is fixed to the wafer chuck 10 on the wafer stage 3. The wafer 2 is fixed to the wafer chuck 10 by utilizing the peripheral portion of the wafer 2 where the pattern is not formed.

Subsequently, the precision alignment mark on the wafer 2 is detected, whereby the fine adjustment of the position of the wafer in the horizontal direction and the direction of rotation is performed (step S204). By detecting the precision alignment mark on the wafer 2, the positional coordinates of the base pattern on the wafer is recorded as a value to the wafer stage coordinates at this stage to form a map centered at the base pattern. This map is used as the value of the center coordinates upon the transfer.

Then, at the stage where the mask substrate 1 and the wafer 2 are placed in a predetermined state before the above-mentioned pattern transfer, the wafer stage 3 is moved to the position of the center coordinates of the first shot (transfer) of the wafer 2 to perform a precise alignment of the wafer 2 (step S205), like the normal pattern transfer apparatus. Specifically, positioning is performed between the center coordinates of the first shot (transfer) of the wafer 2 and the center coordinates of the mask substrate 1. Subsequently, the press-contact unit 9 and the storing unit 11 are driven to press the mask substrate 1 against the wafer 2 and bring the height adjusting unit 4 into contact with the back surface of the wafer 2 (the surface of the wafer 2 opposite to the mask substrate 1) (step S206).

Next, the control unit 5 converts the correction height distribution information h2 calculated based on the positional deviation distribution u(x, y) of the preceding wafer 2a into the voltage that should be applied to each piezoelectric element of the height adjusting unit 4, and applies the voltage to the piezoelectric element to drive the same, thereby adjusting the height distribution in the plane at the transfer position (step S207). The positional deviation between the mask substrate 1 and the wafer 2 can be cancelled with this height adjustment.

Next, the control unit 5 confirms the completion of the process for adjusting the height distribution in the plane at the transfer position, and then, transmits to the resist-curing light irradiating unit 8 an instruction signal for the light irradiation for the resist curing. The resist-curing light irradiating unit 8 irradiates ultraviolet light for the resist curing from the back surface of the mask substrate 1 in accordance with the instruction signal from the control unit 5, thereby transferring the resist pattern having the same shape of the pattern on the mask substrate 1 on the wafer 2 (step S208).

After the pattern is transferred by the irradiation of the ultraviolet light, the press-contact unit 9 and the storing unit 11 are separated from the wafer 2 (step S209). Then, the control unit 5 determines whether the next transfer position is present or not (step S210). When the next transfer position is present (Yes at step S210), the process control returns to step S205 so as to drive the wafer stage 3 to move the same to the center coordinates of the next shot (transfer). Then, the transfer process is repeated by the same process. It is to be noted that the pattern transfer to the wafer 2 can be performed at the other transfer position based on the data of the preceding wafer 2a by the same manner as described above.

On the other hand, when the next transfer position is not present (No at step S210), i.e., when all the desired shots (transfers) on the wafer 2 are completed, the press contact unit 9 and the storing unit 11 are again separated from the wafer 2. After they are sufficiently separated, the wafer 2 on which the pattern has already been transferred is unloaded from the wafer chuck 10 (step S211). After the wafer 2 is unloaded from the wafer chuck 10, the control unit 5 determines whether the next wafer 2 to which the pattern transfer is to be executed is present or not from the presence of the input of a continuation processing signal, for example (step S212).

When there is the next wafer 2 to which the pattern transfer is to be executed (Yes at step S212), the process control returns to step S204 to repeat the transfer process. As described above, the pattern transfer to the succeeding wafer 2 of the same lot is carried out, whereby the pattern transfer is made possible in which the partial distortion of the wafer 2 in the in-plane direction is corrected with the equivalent precision.

On the other hand, when the next wafer 2 to which the pattern transfer is to be executed is not present (No at step S212), a series of transfer process to the wafer 2 of the same lot is completed. After that, the pattern transfer to the wafer 2 for each lot can be carried out by performing the process same as that described above to the wafer 2 of the other lot.

In the above-mentioned pattern transfer process, the correction height distribution information h2 calculated using the preceding wafer 2a is used to perform the pattern transfer to the wafer 2. In this case, the pattern transfer process can be executed by using the correction height distribution information h2 different for every transfer position. Further, it is possible to execute the pattern transfer by using the correction height distribution information h2 same for all transfer positions.

According to the pattern transfer method of the present embodiment, a high-quality pattern transfer having very small positional deviation distribution is made possible in which the partial distortion of the wafer 2 in the in-plane direction at the transfer position is corrected and the positioning precision between the mask substrate 1 and the wafer 2 is remarkably enhanced, like the case of the first embodiment.

Further, according to the pattern transfer method of the present embodiment, when the reproducibility of the positional deviation distribution of the wafer is high such as plural wafers manufactured with the same lot through the same process, the data of the preceding wafer 2a is fed back, whereby the partial distortion of the wafer 2 in the in-plane direction is corrected with the equivalent precision without measuring the positional deviation distribution for each wafer, or without measuring the positional deviation distribution for every shot in each wafer. Therefore, the pattern transfer can be carried out with good mass-productivity.

In a third embodiment of the present invention, another pattern transfer method using the pattern transfer apparatus according to the above-mentioned first embodiment will be explained. It is to be noted that, since the pattern transfer apparatus according to this embodiment is the same as that in the first embodiment, FIG. 1 and the above-mentioned explanation are referred to, and the detailed explanation thereof is not repeated.

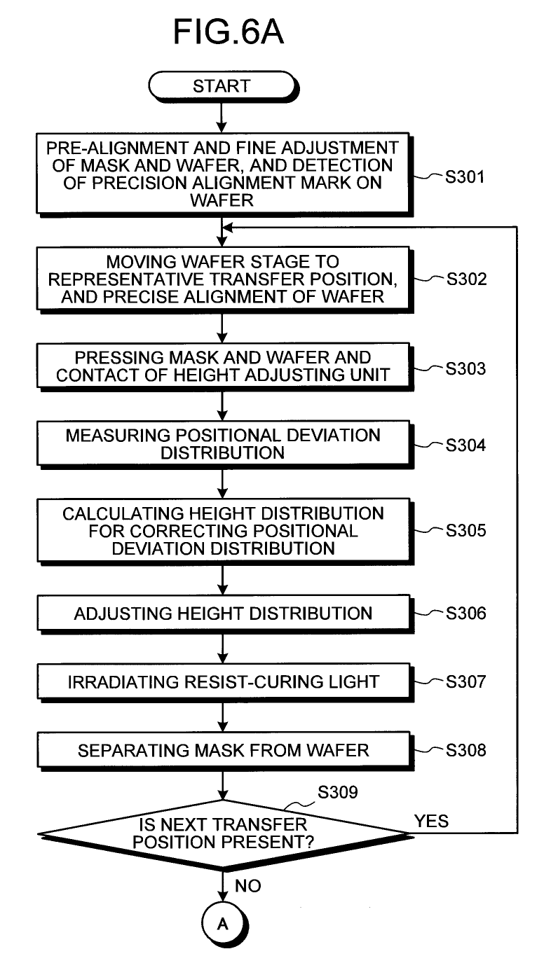

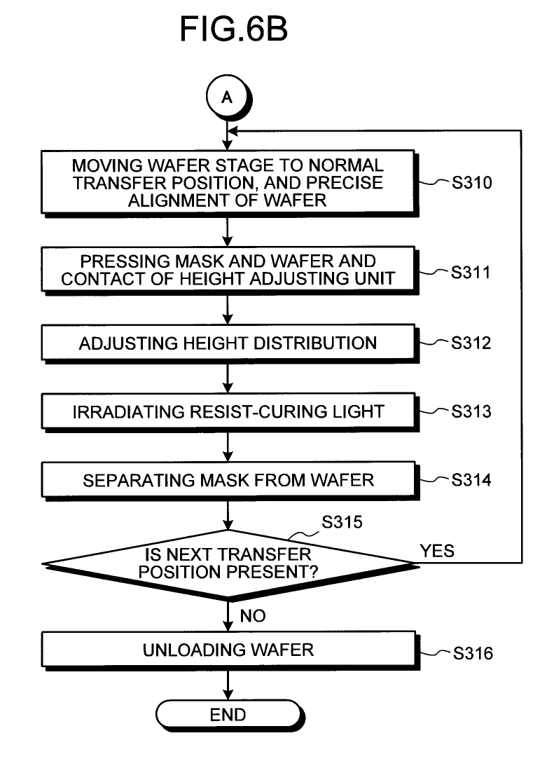

When a great difference is not produced in the positional deviation for every shot (transfer) in each wafer, for example, the following simple method can be employed. In the pattern transfer method according to this embodiment, the positional deviation distribution for the optional representative transfer position among plural transfer positions formed on a single wafer 2 is only measured to calculate the correction height distribution information, and the correction height distribution information at the representative transfer position is applied to the other transfer positions. The pattern transfer method of this embodiment will be explained hereinafter with reference to FIGS. 6A and 6B. FIGS. 6A and 6B are a flowchart of a pattern transfer process according to this embodiment.

The prepared mask substrate 1 is subjected to a rough adjustment (pre-alignment) of the position in the horizontal direction and the rotation in the horizontal plane by a pre-alignment mechanism (not shown) (step S301), and then, fixed to the mask substrate chuck at the press-contact unit 9. Then, a fine adjustment in the position in the horizontal direction and the rotation in the rotating direction is performed by using a reference mark on the wafer stage 3 (step S301).

The wafer 2 having the resist applied thereon is also subjected to a rough adjustment (pre-alignment) in the position in the horizontal direction and the rotation in the horizontal plane with a notch defined as a reference by a pre-alignment mechanism (not shown), like the mask substrate (step S301), and then, fixed to the wafer chuck 10 on the wafer stage 3. The wafer 2 is fixed to the wafer chuck 10 by utilizing the portion of the periphery of the wafer 2 where the pattern is not formed.

Subsequently, the precision alignment mark on the wafer 2 is detected, whereby the fine adjustment of the position of the wafer in the horizontal direction and the direction of rotation is performed (step S301). By detecting the precision alignment mark on the wafer 2, the positional coordinates of the base pattern on the wafer is recorded as a value to the wafer stage coordinates at this stage to form a map centered at the base pattern. This map is used as the value of the center coordinates upon the transfer.

In this embodiment, the optional transfer position (hereinafter referred to as a representative transfer position) among the plural transfer positions on the surface of the wafer 2 is selected beforehand. The number of the representative transfer position is not particularly limited.

Then, at the stage where the mask substrate 1 and the wafer 2 are placed in a predetermined state before the above-mentioned pattern transfer, the wafer stage 3 is moved to the representative transfer position to perform a precise alignment of the wafer 2 (step S302). Subsequently, the press-contact unit 9 and the storing unit 11 are driven to press the mask substrate 1 against the wafer 2 and bring the height adjusting unit 4 into contact with the back surface of the wafer 2 (the surface of the wafer 2 opposite to the mask substrate 1) (step S303).

With this state, the positional deviation amount between the positional deviation detecting pattern on the mask substrate 1 at the representative transfer position and the positional deviation detecting pattern on the wafer 2 are optically measured at a predetermined position using the positional-deviation distribution measuring unit 6, whereby the positional deviation distribution is measured (step S304). The obtained positional deviation distribution is input to the operation unit 7 to obtain the map h1 of the approximate value of h like the first embodiment.

Next, the operation unit 7 makes an approximate polynomial to the map h1 of the approximate value to obtain each coefficient of the polynomial, by the same manner as in the first embodiment. The obtained coefficient of the polynomial is sent to the control unit 5 as data. The control unit 5 obtains the height distribution information h2 for correcting the positional deviation distribution by using the coefficient of the polynomial received from the operation unit 7, and calculates the correction height distribution information h2 that should be given to each lattice point of the height adjusting unit 4 (step S305).

Then, the control unit 5 converts the calculated correction height distribution information h2 into the voltage that should be applied to each piezoelectric element of the height adjusting unit 4, and applies the voltage to the piezoelectric element to drive the same for adjusting the height distribution in the plane at the transfer position (step S306). The positional deviation between the mask substrate 1 and the wafer 2 can be cancelled by this height adjustment.

Next, the control unit 5 confirms the completion of the process for adjusting the height distribution in the plane at the transfer position, and then, transmits to the resist-curing light irradiating unit 8 an instruction signal for the light irradiation for the resist curing. The resist-curing light irradiating unit 8 irradiates ultraviolet light for the resist curing from the back surface of the mask substrate 1 in accordance with the instruction signal from the control unit 5, thereby transferring the resist pattern having the same shape of the pattern on the mask substrate 1 on the wafer 2 (step S307).

After the pattern is transferred by the irradiation of the ultraviolet light, the press-contact unit 9 and the storing unit 11 are separated from the wafer 2 (step S308). Then, the control unit 5 determines whether the next representative transfer position is present or not (step S309). When the next representative transfer position is present (Yes at step S309), the process control returns to step S302 so as to drive the wafer stage 3 to move to the next representative transfer position. Then, the pattern transfer process at the representative transfer position is repeated by the same process.

On the other hand, when the next representative transfer position is not present (No at step S309), i.e., when pattern transfer at all the representative transfer positions on the wafer 2 is completed, the pattern transfer process at the other transfer position (hereinafter referred to as “normal transfer position”) where the positional deviation distribution is not measured by the above-mentioned process is then executed.

In order to execute the pattern transfer at the normal transfer position, the wafer stage 3 is firstly moved to the normal transfer position to perform the precise alignment of the wafer 2 (step S310). Then, the press-contact unit 9 and the storing unit 11 are driven to press the mask substrate 1 against the wafer 2 and bring the height adjusting unit 4 into contact with the back surface of the wafer 2 (the surface of the wafer 2 opposite to the mask substrate 1) (step S311).

Next, the control unit 5 converts the correction height distribution information h2 calculated upon performing the pattern transfer at the representative transfer position into the voltage that should be applied to each piezoelectric element of the height adjusting unit 4, and applies the voltage to the piezoelectric element to drive the same, thereby adjusting the height distribution in the plane at the transfer position (step S312). The positional deviation between the mask substrate 1 and the wafer 2 can be cancelled with this height adjustment.

The correction height distribution information h2 at the specific representative transfer position can be used for the correction height distribution information h2 used here. Further, the average of the whole correction height distribution information h2 at the plural representative transfer positions can be used, for example. The average of the correction height distribution information h2 at the representative transfer position at the neighborhood of the normal transfer position can be used. Further, the correction height distribution information h2 at the representative transfer position at the neighborhood of the normal transfer position is adjusted by using a predetermined correction equation, and the adjusted one can be used.

Next, the control unit 5 confirms the completion of the process for adjusting the height distribution in the plane at the transfer position, and then, transmits to the resist-curing light irradiating unit 8 an instruction signal for the light irradiation for the resist curing. The resist-curing light irradiating unit 8 irradiates ultraviolet light for the resist curing from the back surface of the mask substrate 1 in accordance with the instruction signal from the control unit 5, thereby transferring the resist pattern having the same shape of the pattern on the mask substrate 1 on the wafer 2 (step S313).

After the pattern is transferred by the irradiation of the ultraviolet light, the press-contact unit 9 and the storing unit 11 are separated from the wafer 2 (step S314). Then, the control unit 5 determines whether the next normal transfer position is present or not (step S315). When the next normal transfer position is present (Yes at step S315), the process control returns to step S310 so as to drive the wafer stage 3 to move the same to the center coordinates of the next shot (transfer). Then, the transfer process is repeated by the same process.

On the other hand, when the next normal transfer position is not present (No at step S315), i.e., when all the desired shots (transfers) on the wafer 2 are completed, the press-contact unit 9 and the storing unit 11 are again separated from the wafer 2. After they are sufficiently separated, the wafer 2 on which the pattern has already been transferred is unloaded from the wafer chuck 10 (step S316), whereby a series of transfer process of the wafer 2 is completed. After that, the transfer to the next wafer 2 can be performed by the same process.

According to the pattern transfer method of the present embodiment, a high-quality pattern transfer having very small positional deviation distribution is made possible in which the partial distortion of the wafer 2 in the in-plane direction at the transfer position is corrected and the positioning precision between the mask substrate 1 and the wafer 2 is remarkably enhanced, like the case of the first embodiment.

Further, according to the pattern transfer method of the present embodiment, the positional deviation distribution at all of the plural transfer positions formed on a single wafer 2 is not measured to calculate the correction height distribution information, but the positional deviation distribution at the optional transfer position (representative transfer position) among the plural transfer positions formed on the wafer 2 is only measured to calculate the correction height distribution information. This correction height distribution information is applied to the other transfer position (normal transfer position) whose positional deviation distribution is not measured. Therefore, the pattern transfer can be carried out with good mass-productivity with a simple method.

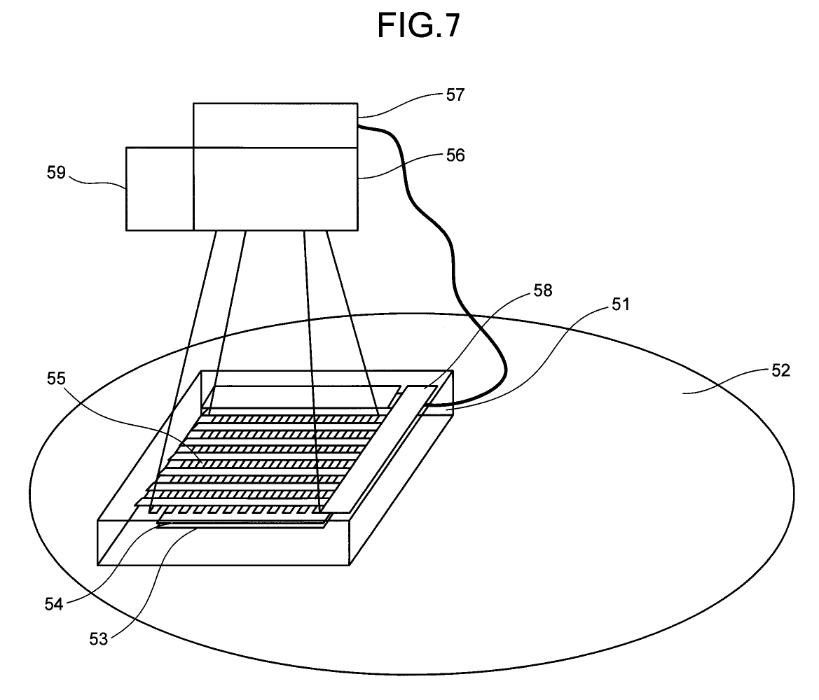

FIG. 7 is a schematic diagram of a pattern transfer apparatus according to a fourth embodiment of the present invention. This pattern transfer apparatus is for realizing a same size contact transfer by the pattern transfer method, like the pattern transfer apparatus according to the first embodiment. The pattern transfer apparatus includes a mask substrate 51, a positional-deviation distribution measuring unit 56, an operation unit 57, and a resist-curing light irradiating unit 59. The mask substrate 51, the positional-deviation distribution measuring unit 56, the operation unit 57, and the resist-curing light irradiating unit 59 respectively correspond to the above-mentioned mask substrate 1, the positional-deviation distribution measuring unit 6, the operation unit 7, and the resist-curing light irradiating unit 8.

In addition to the above-mentioned these components, the pattern transfer apparatus according to this embodiment has the wafer stage 3, the control unit 5, the press-contact unit 9, the wafer chuck 10, and the like, like the pattern transfer apparatus of the first embodiment, wherein the parts common to those in the first embodiment are partly omitted from an illustrative viewpoint. Therefore, for these components, the above-mentioned explanation and FIG. 1 are referred to.

In the pattern transfer apparatus according to the present embodiment, the mask substrate 51, which is an original plate, is arranged so as to be opposite to a wafer 52, which is a substrate to which a pattern is to be transferred, as held at the press-contact unit 9. The wafer 52 is held at the wafer chuck 10 so as to be movable in the in-plane direction of the wafer stage 3 thereon.

As for the mask substrate 51, a crystal 54 that is a crystal of quartz is bonded by a direct bonding to the back surface of the transfer pattern unit 53 formed on a quartz glass having a thickness of 100 μm. The mask substrate 51 has formed thereon a thin-film transistor (TFT) made of zinc oxide (ZnO) known as a transparent semiconductor and a transparent electrode 55 made of indium tin oxide (ITO) and laminated in a lattice of 1 mm pitch. The crystal 54 is a transparent piezoelectric member having a piezoelectric effect, as is well known.

In the pattern transfer apparatus according to the present invention, the positional-deviation distribution measuring unit 56 can measure the relative positional deviation between the pattern on the mask substrate 51 and the pattern on the wafer 52 with the mask substrate 51 brought into pressure contact with the wafer 52. The result of this measurement is converted by the operation unit 57 into a control signal for the crystal 54 providing the piezoelectric effect, and transmitted to a control unit 58.

The resist-curing light irradiating unit 59 irradiates ultraviolet light, which is necessary for curing the resist, to the resist on the wafer 52 through the mask substrate 51 based upon the signal from the control unit 58 and the operation unit 57, after the positioning of the mask substrate 51 and the wafer 52 is completed.

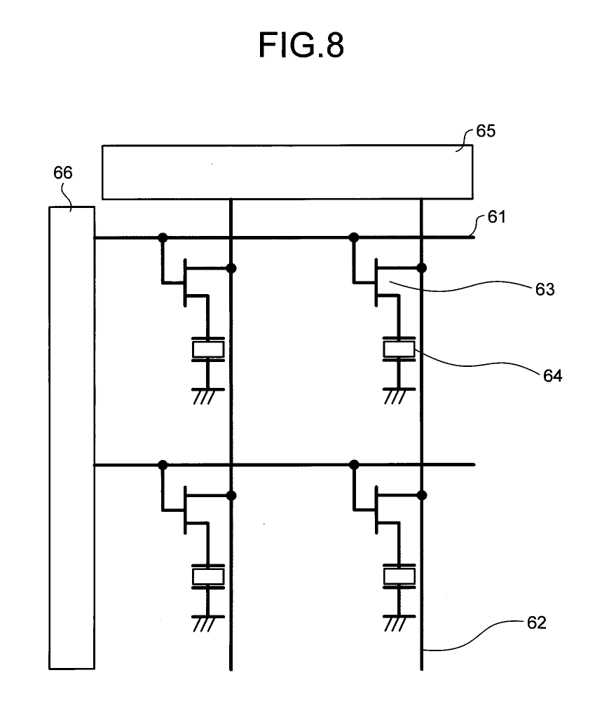

FIG. 8 is an equivalent circuit diagram of the mask substrate 51. The lattice transparent electrode 55 in FIG. 7 is divided into lines 61 and rows 62 as shown in FIG. 8. The lines 61 are connected to the gate of a TFT 63, and the rows 62 are connected to the source of the TFT 63. The crystal 54 explained in FIG. 7 is an insulator, so that it is electrically equivalent to the condenser divided in parallel. A condenser 64 shown in FIG. 8 corresponds to this condenser, one end of which is connected to the drain of the TFT 63 and the other end of which is connected to the ground electrode made of the wafer 52.

Since the condenser 64 functions as the piezoelectric element, it contracts in proportion to the charges accumulated at the condenser 64 at each lattice point (at the intersection of the line 61 and the row 62). Therefore, a line decoder 66 and a row decoder 65, which are a part of the control unit 58, are used to perform the circuit operation same as that of DRAM, whereby desired charges are accumulated at each lattice point, and hence, desired expansion distribution can be provided.

Specifically, supposing that the charges accumulated at each condenser is defined as Q, the electrostatic capacity is defined as C, the effective thickness of the piezoelectric element is defined as t, electromechanical coupling coefficient is defined as d, and Poisson's ratio of the mask substrate is defined as v, the following approximate equation (1) is established between the distortion v and the charge Q.

$$Q ∼ C \frac{t}{( 1 + v ) d} div ( v ) \qquad ( 1 )$$

Accordingly, the charges Q that should be accumulated at each condenser 64 can be obtained from this approximate equation (1) with the measured positional deviation amount as an input. By forming this charge distribution, the positional deviation between the mask substrate 51 and the wafer 52 in the in-plane direction of the wafer can be cancelled.

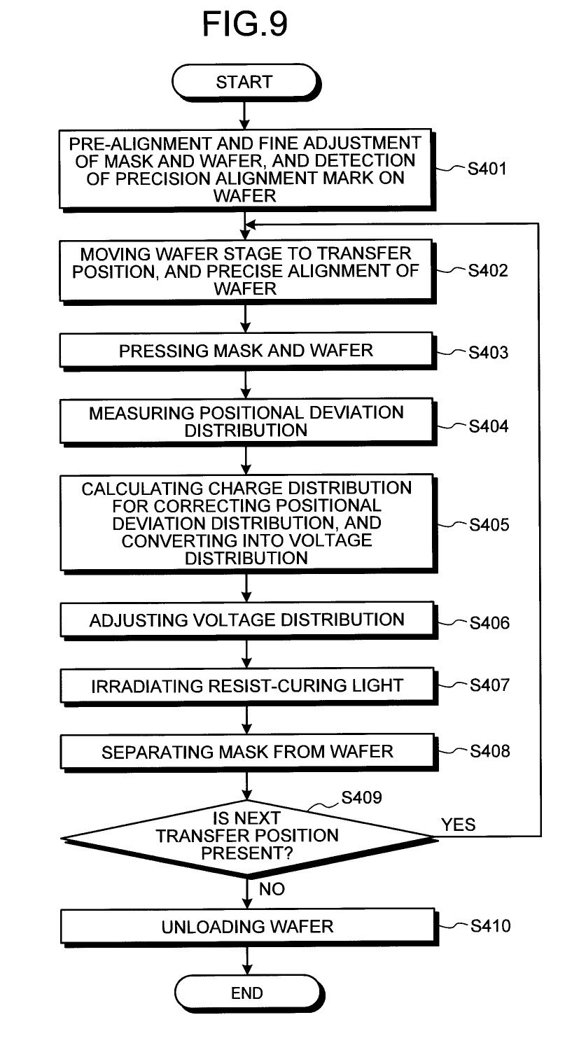

Subsequently, the actual pattern transfer method using the transfer apparatus according to the present embodiment will be explained with reference to FIG. 9. FIG. 9 is a flowchart of a pattern transfer process according to the present embodiment. Firstly, a pattern for detecting the positional deviation is formed beforehand on the mask substrate 51, which is an original plate, with the circuit pattern. It is to be noted that a part of the circuit pattern can be used for the detection of the positional deviation.

The wafer 52, which is a substrate to which a pattern is to be transferred, is, for example, a silicon wafer having a thickness of 720 μm. A base pattern is formed beforehand on the wafer 52, and ultraviolet curing type resist is applied thereon. The base pattern here includes the pattern for the detection of the positional deviation with the circuit pattern. It is to be noted that a part of the circuit pattern can also be used for the detection of the positional deviation.

The prepared mask substrate 51 is subjected to a rough adjustment (pre-alignment) of the position in the horizontal direction and the rotation in the horizontal plane by a pre-alignment mechanism (not shown) (step S401), and then, fixed to the mask substrate chuck at the press-contact unit. Then, a fine adjustment in the position in the horizontal direction and the rotation in the rotating direction is performed by using a reference mark on the wafer stage (step S401).

The wafer 52 having the resist applied thereon is also subjected to a rough adjustment (pre-alignment) in the position in the horizontal direction and the rotation in the horizontal plane with a notch defined as a reference by a pre-alignment mechanism (not shown), like the mask substrate 51 (step S401), and then, fixed to the wafer chuck 10 on the wafer stage 3. The wafer 52 is fixed to the wafer chuck 10 by utilizing the portion of the periphery of the wafer 52 where the pattern is not formed.

Subsequently, the precision alignment mark on the wafer 52 is detected, whereby the fine adjustment of the position of the wafer in the horizontal direction and the direction of rotation is performed (step S401). By detecting the precision alignment mark on the wafer 52, the positional coordinates of the base pattern on the wafer is recorded as a value to the wafer stage coordinates at this stage to form a map centered at the base pattern. This map is used as the value of the center coordinates upon the transfer.

Then, at the stage where the mask substrate 51 and the wafer 52 are placed in a predetermined state before the above-mentioned pattern transfer, the wafer stage 3 is moved to the position of the center coordinates of the first shot (transfer) of the wafer 52 to perform a precise alignment of the wafer 52 (step S402), like the normal pattern transfer apparatus. Specifically, positioning is performed between the center coordinates of the first shot (transfer) of the wafer 52 and the center coordinates of the mask substrate 51. Subsequently, the press-contact unit 9 is driven to press the mask substrate 51 against the wafer 52 (step S403).

With this state, the positional deviation amount between the positional deviation detecting pattern on the mask substrate 51 and the positional deviation detecting pattern on the wafer 52 are optically measured at a predetermined position using the positional-deviation distribution measuring unit 56, whereby the positional deviation distribution is measured (step S404). Supposing that the result of the measurement is defined as v(x, y) (notably, v is a two-dimensional vector amount), the positional deviation amount v(x, y) can be cancelled according to the above-mentioned principle, if Q is obtained by using the equation (1) from the obtained v(x, y). Since the v(x, y) is actually not a continuous value but a discrete value, the differentiation is approximated with the difference, and the map Q1 of the approximate value of Q is obtained at the operation unit 57.

The position of the positional deviation detecting pattern does not always agree with the lattice position of the transparent electrode 55. Therefore, the operation unit 57 makes an approximate polynomial to the map Q1 of the approximate value to obtain each coefficient of the polynomial by the least squares method. The obtained coefficient of the polynomial is sent to the control unit 58 as data.

The control unit 58 calculates the distribution information Q2 of the charges that should be accumulated at each lattice point using the received coefficient of the polynomial. Then, the control unit 58 converts the calculated charge distribution information Q2 into the distribution information of voltage that should be applied to each electrode at each lattice point via the row decoder 65 (S405). The control unit 58 then successively selects each line and circularly applies the obtained voltage to each row, thereby forming the charge distribution to the condenser 64 and forming the desired voltage distribution to the crystal 54 (step S406). Therefore, a distortion due to the piezoelectric effect of the crystal 54 is produced, and the partial correction of the mask substrate 51 in the in-plane direction of the pattern at the transfer position is performed, whereby the positional deviation between the mask substrate 51 and the wafer 52 can be cancelled.

Next, the control unit 58 confirms the completion of the process for forming the desired voltage distribution in the plane at the crystal 54, and then, transmits to the resist-curing light irradiating unit 59 an instruction signal for the light irradiation for the resist curing. The resist-curing light irradiating unit 59 irradiates ultraviolet light for the resist curing from the back surface of the mask substrate 51 in accordance with the instruction signal from the control unit 58, thereby transferring the resist pattern having the same shape of the pattern on the mask substrate 51 on the wafer 52 (step S407).

According to need, the positional deviation distribution can be measured again before the irradiation of the ultraviolet light for confirming whether the positional deviation is cancelled or not. With this operation, a transfer with more reliability can be performed. Further, the fine adjustment in the height can be performed again in accordance with the result of the re-measurement of the positional deviation distribution. This can more surely cancel the positional deviation, so that a transfer having more reliability can be performed. A feedback loop can be provided between the measurement of the positional deviation distribution and the height adjustment.

After the pattern is transferred by the irradiation of the ultraviolet light, the press-contact unit 9 is separated from the wafer 52 to make the mask substrate 51 apart from the wafer 52 (step S408). Then, the control unit 58 determines whether the next transfer position is present or not (step S409). When the next transfer position is present (Yes at step S409), the process control returns to step S402 so as to drive the wafer stage 3 to move the same to the center coordinates of the next shot (transfer). Then, the transfer process is repeated by the same process.

On the other hand, when the next transfer position is not present (No at step S409), i.e., when all the desired shots (transfers) on the wafer 52 are completed, the press-contact unit 9 is again separated from the wafer 52. After they are sufficiently separated, the wafer 52 on which the pattern has already been transferred is unloaded from the wafer chuck 10 (step S410), whereby a series of transfer process of the wafer 52 is completed. After that, the transfer to the next wafer 52 can be performed by the process same as steps S401 to S410.

The aforesaid series of transfer process is executed using the pattern transfer apparatus according to the present embodiment, whereby a high-quality pattern transfer having very small positional deviation distribution is made possible in which the partial correction of the mask substrate 51 in the in-plane direction at the transfer position is performed by using the piezoelectric effect of the crystal 54 and the positioning precision between the mask substrate 51 and the wafer 52 is remarkably enhanced.

In a fifth embodiment of the present invention, another pattern transfer method using the pattern transfer apparatus according to the above-mentioned fourth embodiment will be explained. It is to be noted that, since the pattern transfer apparatus according to this embodiment is the same as that in the fourth embodiment, FIGS. 7, 8 and 1 and the above-mentioned explanation are referred to, and the detailed explanation thereof is not repeated.

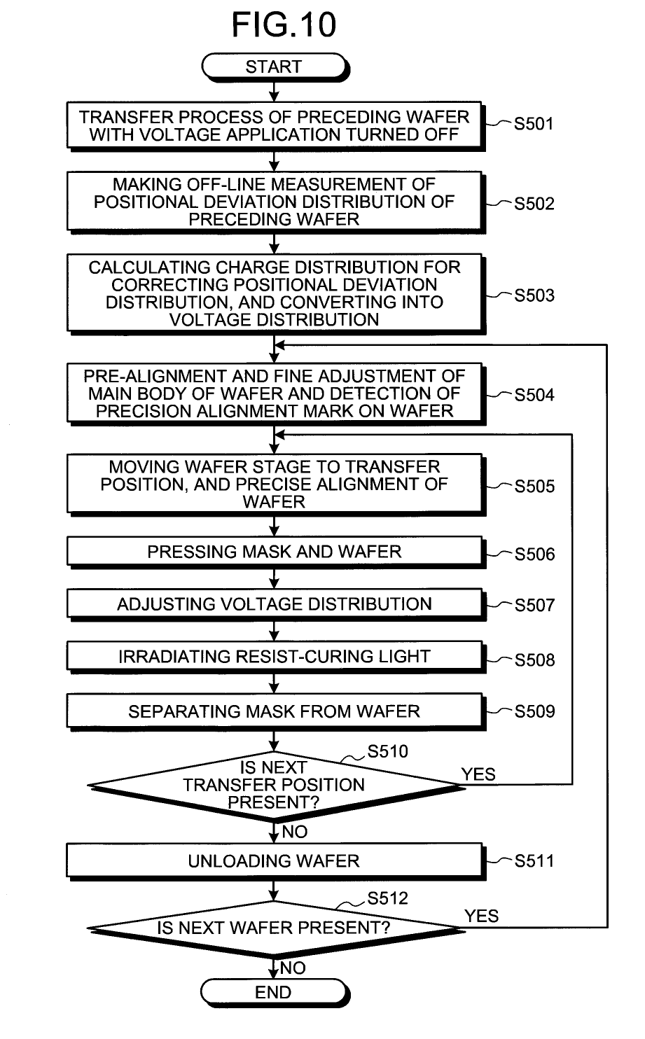

This embodiment explains the pattern transfer method in which the reproducibility in the positional deviation distribution of the wafer is high, such as plural wafers manufactured by, for example, the same lot through the same process. When the reproducibility in the positional deviation distribution is high, and the measurement of the positional deviation distribution for each wafer or the measurement of the positional deviation distribution for each shot in each wafer is unnecessary, the following simple method can be employed. This will be explained hereinafter with reference to FIG. 10. FIG. 10 is a flowchart of a pattern transfer process according to this embodiment.

Firstly, a pattern transfer is performed to a dummy wafer (hereinafter referred to as preceding wafer 52a) for measuring the positional deviation distribution and the positional deviation distribution at the shot (transfer) in the wafer. The normal pattern transfer to the preceding wafer 52a is carried out with the voltage application to the crystal 54 turned off, i.e., with the whole portion of the crystal 54 not displaced (step S501). In this pattern transfer, the above-mentioned steps S401 to S403 are executed as the preliminary process.

Next, the preceding wafer 52a to which the pattern has been transferred is unloaded from the pattern transfer apparatus, and the positional deviation distribution v(x, y) is measured by using the off-line positional deviation measuring device (step S502). It is to be noted that the off-line measuring function can be provided to the positional-deviation distribution measuring unit 56 of the pattern transfer apparatus for measuring the positional deviation distribution. Further, the obtained positional deviation distribution is input to the operation unit 57, whereby the map Q1 of the approximate value Q is obtained by the same manner as in the fourth embodiment.

Subsequently, the operation unit 57 makes an approximate polynomial to the map Q1 of the approximate value to obtain each coefficient of the polynomial by the same manner as in the fourth embodiment. The obtained coefficient of the polynomial is sent to the control unit 58 as data. The control unit 58 calculates the distribution information Q2 of the charges that should be applied to each electrode at each lattice point using the coefficient of the polynomial received from the operation unit 57. Then, the control unit 58 converts the calculated distribution information Q2 of the charges into the distribution information of the voltage that should be applied to each electrode at each lattice point via the row decoder 65 (step S503).

Next, the pattern transfer to the main body wafer (hereinafter referred to as wafer 52), which is to be a product, is carried out. Since the rough adjustment (pre-alignment) and fine adjustment of the mask substrate 51 has already been completed as the preliminary process, the rough adjustment (pre-alignment) and fine adjustment for the wafer 52 having the resist applied thereon is executed. Specifically, the rough adjustment (pre-alignment) of the position in the horizontal direction and the rotation in the horizontal plane is carried out with the notch defined as a reference by using a pre-alignment mechanism (not shown) (step S504), like the case of the mask substrate 51, and then, the wafer 52 is fixed to the wafer chuck 10 on the wafer stage 3. The wafer 52 is fixed to the wafer chuck 10 by utilizing the peripheral portion of the wafer 52 where the pattern is not formed.

Subsequently, the precision alignment mark on the wafer 52 is detected, whereby the fine adjustment of the position of the wafer in the horizontal direction and the direction of rotation is performed (step S504). By detecting the precision alignment mark on the wafer 52, the positional coordinates of the base pattern on the wafer is recorded as a value to the wafer stage coordinates at this stage to form a map centered at the base pattern. This map is used as the value of the center coordinates upon the transfer.

Then, at the stage where the mask substrate 51 and the wafer 52 are placed in a predetermined state before the above-mentioned pattern transfer, the wafer stage 3 is moved to the position of the center coordinates of the first shot (transfer) of the wafer 52 to perform a precise alignment of the wafer 52 (step S505), like the normal pattern transfer apparatus. Specifically, positioning is performed between the center coordinates of the first shot (transfer) of the wafer 52 and the center coordinates of the mask substrate 51. Subsequently, the press-contact unit 9 is driven to press the mask substrate 51 against the wafer 52 (step S506).

Next, the control unit 58 successively selects each line and circularly applies the obtained voltage to each row based on the distribution information of the voltage that should be applied to each electrode at each lattice point, which is obtained at the preceding wafer 52a, thereby forming the charge distribution to the condenser 64 and forming the desired voltage distribution to the crystal 54 (step S507). Therefore, a distortion due to the piezoelectric effect of the crystal 54 is produced, and the partial correction of the mask substrate 51 in the in-plane direction of the pattern at the transfer position is performed, whereby the positional deviation between the mask substrate 51 and the wafer 52 can be cancelled.

Next, the control unit 58 confirms the completion of the process for forming the desired voltage distribution in the plane of the crystal 54, and then, transmits to the resist-curing light irradiating unit 59 an instruction signal for the light irradiation for the resist curing. The resist-curing light irradiating unit 59 irradiates ultraviolet light for the resist curing from the back surface of the mask substrate 51 in accordance with the instruction signal from the control unit 58, thereby transferring the resist pattern having the same shape of the pattern on the mask substrate 51 on the wafer 52 (step S508).

After the pattern is transferred by the irradiation of the ultraviolet light, the press-contact unit 9 is separated from the wafer 52 so as to make the mask substrate 51 apart from the wafer 52 (step S509). Then, the control unit 58 determines whether the next transfer position is present or not (step S510). When the next transfer position is present (Yes at step S510), the process control returns to step S505 so as to drive the wafer stage 3 to move the same to the center coordinates of the next shot (transfer). Then, the transfer process is repeated by the same process.

On the other hand, when the next transfer position is not present (No at step S510), i.e., when all the desired shots (transfers) on the wafer 52 are completed, the press-contact unit 9 is again separated from the wafer 52. After they are sufficiently separated, the wafer 52 on which the pattern has already been transferred is unloaded from the wafer chuck 10 (step S511). After the wafer 52 is unloaded from the wafer chuck 10, the control unit 58 determines whether the next wafer 52 to which the pattern transfer is to be executed is present or not from the presence of the input of a continuation processing signal, for example (step S512).

When there is the next wafer 52 to which the pattern transfer is to be executed (Yes at step S512), the process control returns to step S504 to repeat the transfer process. As described above, the pattern transfer to the succeeding wafer 52 of the same lot is carried out, whereby the pattern transfer is made possible in which the partial correction of the mask substrate 51 in the in-plane direction of the pattern at the transfer position is performed with the equivalent precision.

On the other hand, when the next wafer 52 to which the pattern transfer is to be executed is not present (No at step S512), a series of transfer process to the wafer 52 of the same lot is completed. After that, the pattern transfer to the wafer 52 for each lot can be carried out by performing the process same as that described above to the wafer 52 of the other lot.

In the above-mentioned pattern transfer process, the pattern transfer process of the wafer 52 is performed by using the charge distribution information Q2 calculated using the preceding wafer 52a. In this case, the pattern transfer process can be executed by using the charge distribution information Q2 different for every transfer position. Further, it is possible to execute the pattern transfer by using the charge distribution information Q2 same for all transfer positions.

According to the pattern transfer method of the present embodiment, a high-quality pattern transfer having very small positional deviation distribution is made possible in which the partial correction of the mask substrate 51 in the in-plane direction at the transfer position is performed by using the piezoelectric effect of the crystal 54 and the positioning precision between the mask substrate 51 and the wafer 52 is remarkably enhanced, like the fourth embodiment.

Further, according to the pattern transfer method of the present embodiment, when the reproducibility of the positional deviation distribution of the wafer is high such as plural wafers manufactured with the same lot through the same process, the data of the preceding wafer 52a is fed back, whereby the partial correction of the mask substrate 51 in the in-plane direction of the pattern at the transfer position is performed with the equivalent precision without measuring the positional deviation distribution for each wafer, or without measuring the positional deviation distribution for every shot in each wafer. Therefore, the pattern transfer can be carried out with good mass-productivity.

In a sixth embodiment of the present invention, another pattern transfer method using the pattern transfer apparatus according to the above-mentioned fourth embodiment will be explained. It is to be noted that, since the pattern transfer apparatus according to this embodiment is the same as that in the fourth embodiment, FIGS. 7, 8 and 1 and the above-mentioned explanation are referred to, and the detailed explanation thereof is not repeated.

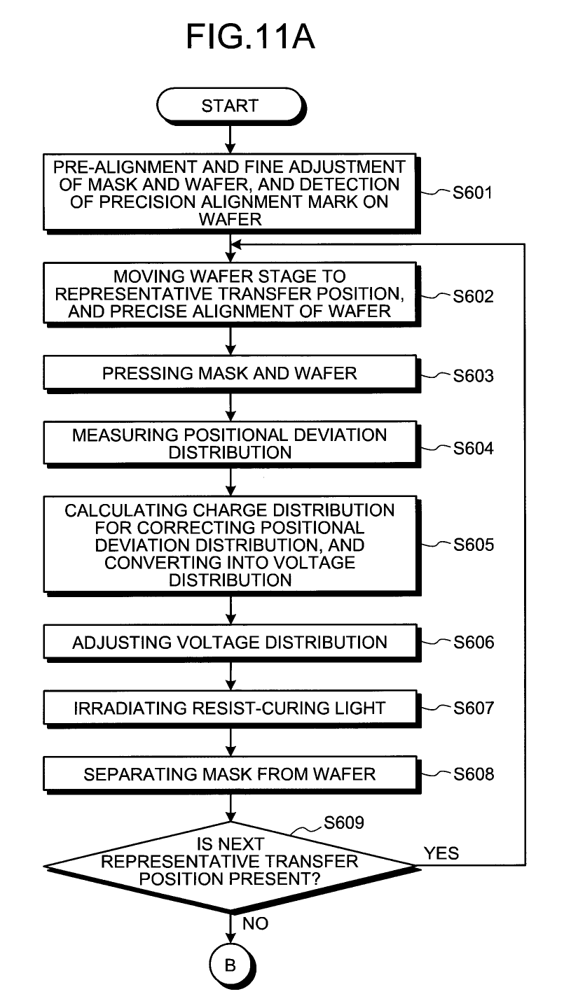

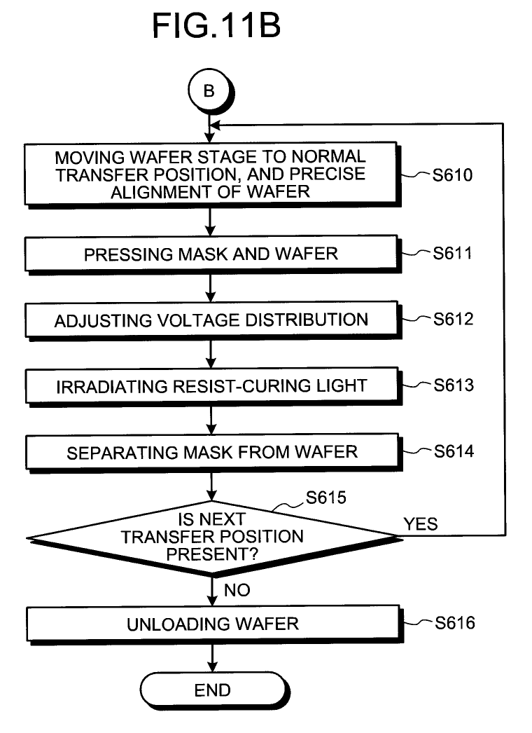

When a great difference is not produced in the positional deviation for every shot (transfer) in each wafer, for example, the following simple method can be employed. In the pattern transfer method according to this embodiment, the positional deviation distribution for the optional representative transfer position among plural transfer positions formed on a single wafer 52 is only measured to calculate the charge distribution information Q2, and the charge distribution information Q2 at the representative transfer position is applied to the other transfer positions. The pattern transfer method of this embodiment will be explained hereinafter with reference to FIGS. 11A and 11B. FIGS. 11A and 11B are a flowchart of a pattern transfer process according to this embodiment.

The prepared mask substrate 51 is subjected to a rough adjustment (pre-alignment) of the position in the horizontal direction and the rotation in the horizontal plane by a pre-alignment mechanism (not shown) (step S601), and then, fixed to the mask substrate chuck at the press-contact unit 9. Then, a fine adjustment in the position in the horizontal direction and the rotation in the rotating direction is performed by using a reference mark on the wafer stage 3 (step S601).

The wafer 52 having the resist applied thereon is also subjected to a rough adjustment (pre-alignment) in the position in the horizontal direction and the rotation in the horizontal plane with a notch defined as a reference by a pre-alignment mechanism (not shown), like the mask substrate (step S601), and then, fixed to the wafer chuck 10 on the wafer stage 3. The wafer 52 is fixed to the wafer chuck 10 by utilizing the portion of the periphery of the wafer 52 where the pattern is not formed.

Subsequently, the precision alignment mark on the wafer 52 is detected, whereby the fine adjustment of the position of the wafer in the horizontal direction and the direction of rotation is performed (step S601). By detecting the precision alignment mark on the wafer 52, the positional coordinates of the base pattern on the wafer is recorded as a value to the wafer stage coordinates at this stage to form a map centered at the base pattern. This map is used as the value of the center coordinates upon the transfer.

In this embodiment, the optional transfer position (hereinafter referred to as a representative transfer position) among the plural transfer positions on the surface of the wafer 52 is selected beforehand. The number of the representative transfer position is not particularly limited.

Then, at the stage where the mask substrate 51 and the wafer 52 are placed in a predetermined state before the above-mentioned pattern transfer, the wafer stage 3 is moved to the representative transfer position to perform a precise alignment of the wafer 52 (step S602). Subsequently, the press-contact unit 9 is driven to press the mask substrate 51 against the wafer 52 (step S603).

With this state, the positional deviation amount between the positional deviation detecting pattern on the mask substrate 51 at the representative transfer position and the positional deviation detecting pattern on the wafer 52 are optically measured at a predetermined position using the positional-deviation distribution measuring unit 56, whereby the positional deviation distribution is measured (step S604). The obtained positional deviation distribution is input to the operation unit 57 to obtain the map Q1 of the approximate value of Q like the fourth embodiment.

Next, the operation unit 57 makes an approximate polynomial to the map Q1 of the approximate value to obtain each coefficient of the polynomial, by the same manner as in the fourth embodiment. The obtained coefficient of the polynomial is sent to the control unit 58 as data. The control unit 58 calculates the distribution information Q2 of the charges that should be accumulated at each lattice point on each electrode by using the coefficient of the polynomial received from the operation unit 57. Then, the control unit 58 converts the calculated charge distribution information Q2 into the distribution information of the voltage that should be applied to each electrode at each lattice point through the row decoder 65 (step S605).

Then, the control unit 58 successively selects each line and circularly applies the obtained voltage to each row, thereby forming the charge distribution to the condenser 64 and forming the desired voltage distribution to the crystal 54 (step S606). Therefore, a distortion due to the piezoelectric effect of the crystal 54 is produced, and the partial correction of the mask substrate 51 in the in-plane direction of the pattern at the transfer position is performed, whereby the positional deviation between the mask substrate 51 and the wafer 52 can be cancelled.

Next, the control unit 58 confirms the completion of the process for forming the desired charge distribution in the plane of the crystal 54, and then, transmits to the resist-curing light irradiating unit 59 an instruction signal for the light irradiation for the resist curing. The resist-curing light irradiating unit 59 irradiates ultraviolet light for the resist curing from the back surface of the mask substrate 51 in accordance with the instruction signal from the control unit 58, thereby transferring the resist pattern having the same shape of the pattern on the mask substrate 51 on the wafer 52 (step S607).

After the pattern is transferred by the irradiation of the ultraviolet light, the press-contact unit 9 is separated from the wafer 52 so as to make the mask substrate 51 apart from the wafer 52 (step S608). Then, the control unit 58 determines whether the next representative transfer position is present or not (step S609). When the next representative transfer position is present (Yes at step S609), the process control returns to step S602 so as to drive the wafer stage 3 to move the same to the center coordinates of the next shot (transfer). Then, the transfer process is repeated by the same process as described above.

On the other hand, when the next representative transfer position is not present (No at step S609), i.e., when pattern transfer at all the representative transfer positions on the wafer 52 is completed, the pattern transfer process at the other transfer position (hereinafter referred to as “normal transfer position”) where the positional deviation distribution is not measured by the above-mentioned process is then executed.

In order to execute the pattern transfer at the normal transfer position, the wafer stage 3 is firstly moved to the normal transfer position to do the precise alignment of the wafer 52 (step S610). Then, the press-contact unit 9 is driven to press the mask substrate 51 against the wafer 52 (step S611).

Next, the control unit 58 successively selects each line and circularly applies the obtained voltage to each row based on the distribution information of the voltage that should be applied to each electrode at each lattice point, which is obtained upon performing the pattern transfer at the representative transfer position, thereby forming the charge distribution to the condenser 64 and forming the desired voltage distribution to the crystal 54 (step S612). Therefore, a distortion due to the piezoelectric effect of the crystal 54 is produced, and the partial correction of the mask substrate 51 in the in-plane direction of the pattern at the transfer position is performed, whereby the positional deviation between the mask substrate 51 and the wafer 52 can be cancelled.

The voltage distribution information at the specific representative transfer position can be used for the voltage distribution information used here. Further, the average of the whole voltage distribution information at the plural representative transfer positions can be used, for example. The average of the voltage distribution information at the representative transfer position at the neighborhood of the normal transfer position can be used. Further, the voltage distribution information at the representative transfer position at the neighborhood of the normal transfer position is adjusted by using a predetermined correction equation, and the adjusted one can be used.

Next, the control unit 58 confirms the completion of the process for forming the desired voltage distribution in the plane of the crystal 54, and then, transmits to the resist-curing light irradiating unit 59 an instruction signal for the light irradiation for the resist curing. The resist-curing light irradiating unit 59 irradiates ultraviolet light for the resist curing from the back surface of the mask substrate 51 in accordance with the instruction signal from the control unit 58, thereby transferring the resist pattern having the same shape of the pattern on the mask substrate 51 on the wafer 52 (step S613).

After the pattern is transferred by the irradiation of the ultraviolet light, the press-contact unit 9 is separated from the wafer 52 so as to make the mask substrate 51 apart from the wafer 52 (step S614). Then, the control unit 58 determines whether the next normal transfer position is present or not (step S615). When the next normal transfer position is present (Yes at step S615), the process control returns to step S610 so as to drive the wafer stage 3 to move the same to the center coordinates of the next shot (transfer). Then, the transfer process is repeated by the same process.

On the other hand, when the next normal transfer position is not present (No at step S615), i.e., when all the desired shots (transfers) on the wafer 2 are completed, the press-contact unit 9 is again separated from the wafer 52. After they are sufficiently separated, the wafer 52 on which the pattern has already been transferred is unloaded from the wafer chuck 10 (step S616), whereby a series of transfer process of the wafer 52 is completed. After that, the transfer to the next wafer 52 can be performed by the same process.

According to the pattern transfer method of the present embodiment, a high-quality pattern transfer having very small positional deviation distribution is made possible in which the partial correction of the mask substrate 51 in the in-plane direction at the transfer position is performed and the positioning precision between the mask substrate 51 and the wafer 52 is remarkably enhanced, like the fourth embodiment.

Further, according to the pattern transfer method of the present embodiment, the positional deviation distribution at all of the plural transfer positions formed on a single wafer 52 is not measured, but the positional deviation distribution at the optional transfer position (representative transfer position) among the plural transfer positions formed on the wafer 52 is only measured. The data at the representative transfer position is fed back and the same data is applied to the other transfer position (normal transfer position) whose positional deviation distribution is not measured. Therefore, the pattern transfer can be carried out with good mass-productivity with a simple method without measuring the positional deviation distribution at each transfer position.

The present invention is not limited to the above-mentioned each embodiment. In the above-mentioned embodiments, a step and flash imprint lithography is utilized that uses an ultraviolet curing type resist. However, the present invention is applicable to a microcontact lithography in which a resist material is adhered onto the leading end of the mask substrate and only the leading end is brought into contact with the wafer, thereby forming a pattern.

The present invention can also be applied to a batch transfer in which a pattern is collectively formed on the whole surface of the wafer without moving the wafer stepwise. Moreover, a PZT or crystal is used as the piezoelectric element, but other materials such as lead lanthanum zirconate titanate (PLZT) can be used. The present invention can be modified within the range not departing from the spirit of the present invention.

It is unnecessary to form the mask substrate and the wafer, which has been not yet subjected to the transfer process, in the idealistic flat state in the in-plane direction. Even when the mask substrate and the wafer, which has been not yet subjected to the transfer process, are not in the idealistic flat state in the in-plane direction, a high-quality pattern transfer having very small positional deviation distribution is made possible in which the positioning precision between the mask substrate and the wafer is remarkably enhanced due to the execution of the correction, like the above-mentioned case.

Exemplary embodiments of a method of manufacturing a semiconductor device and an apparatus for manufacturing the semiconductor device are described in detailed in a seventh embodiment of the present invention.

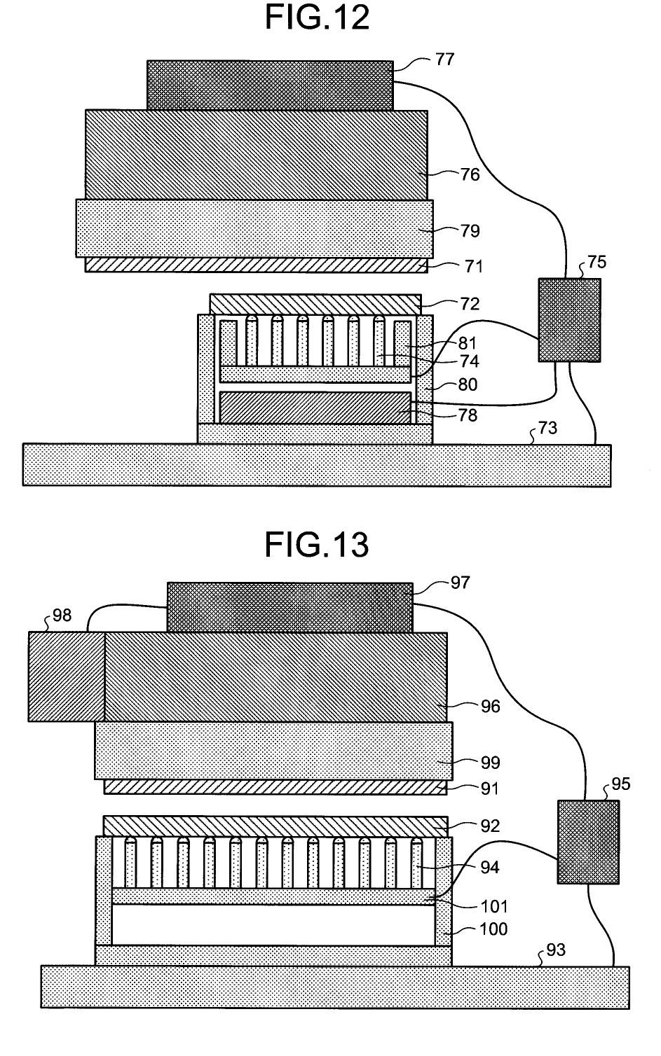

FIGS. 12 and 13 are schematic diagrams of apparatuses for manufacturing a semiconductor device according to a seventh embodiment of the present invention. These apparatuses for manufacturing a semiconductor device are a substrate bonding-device for achieving a method of manufacturing a semiconductor device according to an embodiment of the present invention. The apparatus for manufacturing a semiconductor device shown in FIG. 12 is a first substrate-bonding device that is used for bonding substrates (wafers) having a different size. The apparatus for manufacturing a semiconductor device shown in FIG. 13 is a second substrate-bonding device that is used for bonding substrates (wafers) having a substantially same size. The substrate hereinafter indicates a base substrate on which a layer such as an element layer is formed. However, it is possible to bond simple base substrates to each other by using the method of manufacturing a semiconductor device and the apparatus for manufacturing a semiconductor device described later.

As shown in FIG. 12, the first substrate-bonding device includes a wafer stage 73, a height adjusting unit 74, a control unit 75, a positional-deviation distribution measuring unit 76, an operation unit 77, a substrate stripper-light irradiating unit 78, a press-contact unit 79, a wafer chuck 80, and a storing unit 81.

In the first substrate-bonding device, a wafer 71 that functions as a first substrate is held by the press-contact unit 79 through vacuum contact such that the wafer 71 is faced to a wafer 72 that functions as a second substrate. The wafer 72 is supported by the wafer chuck 80 that is carried by the wafer stage 73 in a manner movable in the in-plane direction of the wafer stage 73 on a surface of the wafer stage 73. The height adjusting unit 74 adjusts a height of a portion of the wafer 72. The height adjusting unit 74 is arranged in a lattice shaped between the wafer 72 that is supported by the wafer chuck 80 and the wafer stage 73 such that the height adjusting unit 74 covers an element area of the wafer 72. The height adjusting unit 74 is housed in the storing unit 81. The motion of the wafer stage 73 and the motion of the height adjusting unit 74 are controlled by the control unit 75.

The press-contact unit 79 pushes the wafer 71 close to the wafer 72 and then presses the wafer 71 against the wafer 72. The operation of the press-contact unit 79 is separated into two stages. At the first stager the press-contact unit 79 pushes the wafer 71 to a position several tens-of-micrometers or closer to, i.e., not contacting with, the wafer 72. At the second stage, the press-contact unit 79 pushes the wafer 71 to a position perfectly contact with the wafer 72 with no gap between the wafer 71 and the wafer 72, and presses the wafer 71 against the wafer 72.

At the first stage, the positional-deviation distribution measuring unit 76 measures a relative positional deviation between a pattern on the wafer 71 and a pattern on the wafer 72 in the state of the wafer 71 is at the position close to the wafer 72. A result of the measuring is converted by the operation unit 77 into a control signal for controlling the height adjusting unit 74. The control signal is sent to the control unit 75.

The wafer 71 and the wafer 72 are bonded with each other through a direct bonding not using an adhesive agent or the like. The direct bonding is a technique of bonding planes by coming two planes having a flatly-polished bond surface in contact with each other at a room temperature. The direct bonding does not use both an adhesive agent and a heating process, which makes it possible to bond even planes made of a different material at a high precision. After the positional alignment between the wafer 71 and the wafer 72 based on the signals output from the control unit 75 and the operation unit 77 is completed, the press-contact unit 79 presses the wafer 71 against the wafer 72, that is, comes the wafer 71 in contact with the wafer 72 thereby directly bonding the wafer 71 and the wafer 72.

The two-staged operation of the press-contact unit 79 makes it possible to ensure in-plane direction positional alignment between the wafer 71 and the wafer 72. If a part of the wafer 71 contacts with the wafer 72, the contacted part starts bonding with the wafer 72. The bonded part inhibits the positional alignment. The in-plane direction positional alignment is performed in the state a gap between the wafer 71 and the wafer 72 is several tens-of-micrometers or narrower. The wafer 71 and the wafer 72 are bonded with each other through the second-stage press-contact operation that is performed after it is confirmed that the position alignment is completed. This allows achieving the high positional-alignment precision.

In the step of press-contact operation, the vacuum contact between the wafer 71 and the press-contact unit 79 is released at the press-contact operation, which allows obtaining uniform bonding.

The substrate stripper-light irradiating unit 78 strips an element layer off from its substrate by irradiating a stripper light to a later-described stripper layer. The wafer 72 includes the stripper layer arranged between the element layer and the substrate. After the wafer 71 and the wafer 72 are bonded with each other, the wafer 72 that is in a state of the element layer of the wafer 72 is bonded with the wafer 71 is exposed with the stripper light so that the element layer of the wafer 72 is stripped off from the substrate of the wafer 72.

As shown in FIG. 13, the second substrate-bonding device includes a wafer stage 93, a height adjusting unit 94, a control unit 95, a positional-deviation distribution measuring unit 96, an operation unit 97, a substrate stripper-light irradiating unit 98, a press-contact unit 99, a wafer chuck 100, and a storing unit 101.

In the second substrate-bonding device, a wafer 91 that functions as a first substrate is held by the press-contact unit 99 through vacuum contact such that the wafer 91 is faced to a wafer 92 that functions as a second substrate. The wafer 92 is supported by the wafer chuck 100 that is carried by the wafer stage 93 in a manner movable in the in-plane direction of the wafer stage 93 on a surface of the wafer stage 93.

The height adjusting unit 94 adjusts a height of a portion of the wafer 92. The height adjusting unit 94 is arranged in a lattice shaped between the wafer 92 and the wafer stage 93 such that the height adjusting unit 94 almost entirely covers the wafer 92 excluding a periphery having an 8-mm width. The height adjusting unit 94 is housed in the storing unit 101. Because a movable distance in the second bonding-device can be much smaller than that in the first bonding-device, a bearing of the storing unit 101 that houses the height adjusting unit 94 can be attached to the wafer chuck 100. The motion of the wafer stage 93 and the motion of the height adjusting unit 94 are controlled by the control unit 95.

The press-contact unit 99 pushes the wafer 91 close to the wafer 92 and then presses the wafer 91 against the wafer 92. The operation of the press-contact unit 99 is separated into two stages. At the first stage, the press-contact unit 99 pushes the wafer 91 to a position several tens-of-micrometers or closer to, i.e., not contacting with, the wafer 92. At the second stage, the press-contact unit 99 pushes the wafer 91 to a position perfectly contact with the wafer 92 with no gap between the wafer 91 and the wafer 92, and presses the wafer 91 against the wafer 92.

At the first stage, the positional-deviation distribution measuring unit 96 measures a relative positional deviation between a pattern on the wafer 91 and a pattern on the wafer 92 in the state of the wafer 91 is at the position close to the wafer 92. A result of the measuring is converted by the operation unit 97 into a control signal for controlling the height adjusting unit 94. The control signal is sent to the control unit 95.

The wafer 91 and the wafer 92 are bonded with each other through a direct bonding not using an adhesive agent or the like. The direct bonding is a technique of bonding planes by coming two planes having a flatly-polished bond surface in contact with each other at a room temperature. The direct bonding does not use both an adhesive agent and a heating process, which makes it possible to bond even planes made of a different material at a high precision. After the positional alignment between the wafer 91 and the wafer 92 based on the signals output from the control unit 95 and the operation unit 97 is completed, the press-contact unit 99 presses the wafer 91 against the wafer 92, that is, comes the wafer 91 in contact with the wafer 92 thereby directly bonding the wafer 91 and the wafer 92.

The two-staged operation of the press-contact unit 99 makes it possible to ensure in-plane direction positional alignment between the wafer 91 and the wafer 92. If a part of the wafer 91 contacts with the wafer 92, the contacted part starts bonding with the wafer 92. The bonded part inhibits the positional alignment. The in-plane direction positional alignment is performed in the state a gap between the wafer 91 and the wafer 92 is several tens-of-micrometers or narrower. The wafer 91 and the wafer 92 are bonded with each other through the second-stage press-contact operation that is performed after it is confirmed that the position alignment is completed. This allows achieving the high positional-alignment precision.

In the step of press-contact operation, the vacuum contact between the wafer 91 and the press-contact unit 99 is released at the press-contact operation, which allows obtaining uniform bonding.

The substrate stripper-light irradiating unit 98 strips an element layer off from its substrate by irradiating a stripper light to a later-described stripper layer. The wafer 91 includes the stripper layer arranged between the element layer and the substrate. After the wafer 91 and the wafer 92 are bonded with each other, the wafer 91 that is in a state of the element layer of the wafer 91 is bonded with the wafer 91 is exposed with the stripper light so that the element layer of the wafer 91 is stripped off from the substrate of the wafer 91.

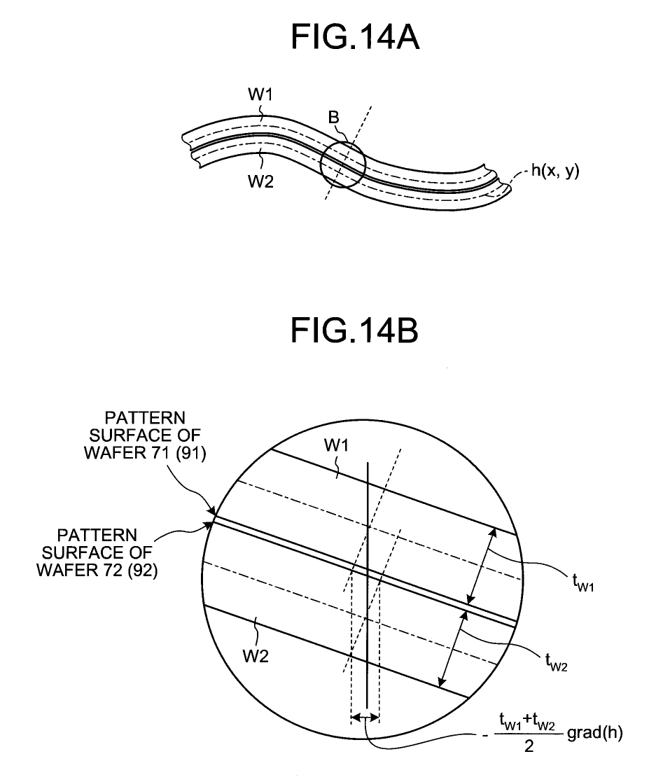

FIG. 14A is a schematic sectional diagram of the wafers 71 and 72 or the wafers 91 and 92 for explaining a principle of correction used in the substrate-bonding devices. FIG. 14B is an enlarged schematic diagram of an area B shown in FIG. 14A. In the first substrate-bonding device shown in FIG. 12 or the second substrate-bonding device shown in FIG. 13, the wafer 71 or 91 is pressed against the wafer 72 or 92 so that a surface shape of the wafer 71 or 91 goes along a surface shape of the wafer 72 or 92.

For the same reason described above in the first embodiment with reference to FIGS. 2A and 2B, the central surface of the wafer 71, 72, 91, or 92 in the thickness direction becomes a neutral surface. As a result, a positional deviation amount at the bonding, which is a sum of a pattern deformation of the wafer 71 or 91 and a pattern deformation of the wafer 72 or 92, is represented by −(tw₁+tw₂)/2*grad(h) where tw₁ is the thickness of the wafer 71 or 91 and tw₂ is the thickness of the wafer 72 or 92. Assuming that the thickness of the wafer 71 or 91 is 400 μm, the thickness of the wafer 72 or 92 is 720 μm, and the deformation in the high direction is 100 nm every 1 mm in the lateral direction, the positional deviation amount is 56 nm.

According to the calculation, if the height can be adjusted by the nm scale, several tens-of-nanometer amount at a portion within the bond area can be corrected. An allowable positional deviation amount is assumed to a one-eight of the wavelength of the light used for transferring signals or smaller. Therefore, the several tens-of-nanometer positional-alignment correction is enough even when a visible light is used.

The bonding using the direct bonding technique includes the press-contact operation. It means that the height adjusting unit 74 or 94 just applies a force in an upward direction, which allows simplifying the structure of the height adjusting unit 74 or 94 thereby reducing costs. In contrary, in a case that a bonding using an adhesive agent, i.e., not including the press-contact operation is applied, a height adjusting unit that is located backside of a wafer not only pushes the wafer upward but also pulls the wafer downward to form a concave face. To enable such complicated motion, additional unit such as a little vacuum chuck is required.

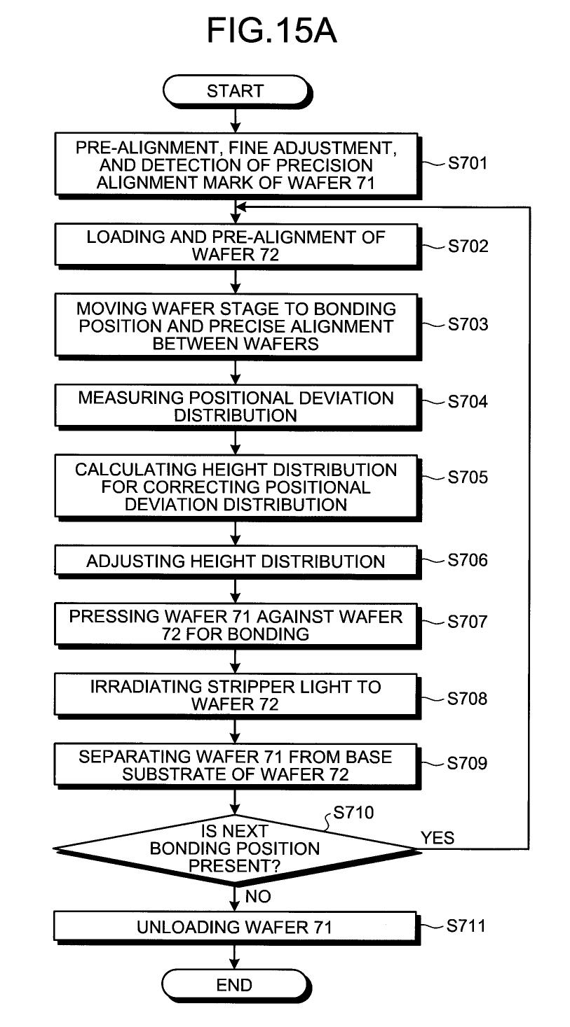

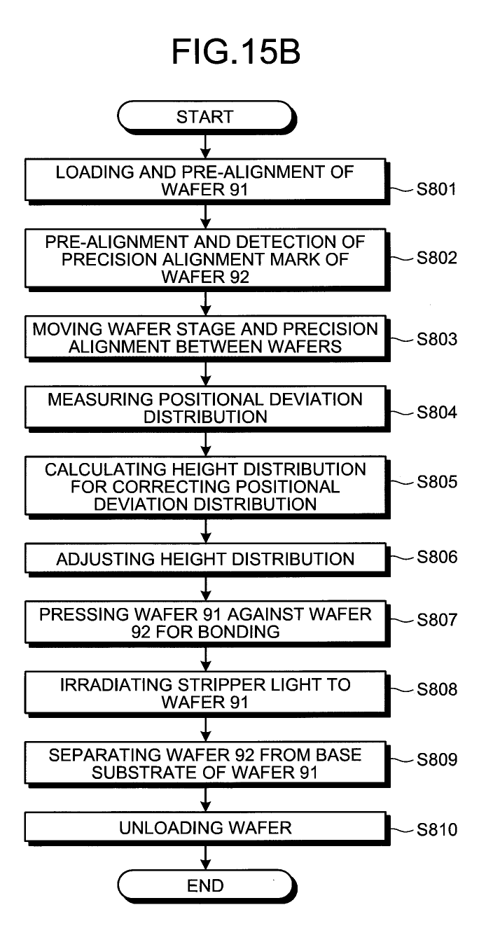

An actual method of bonding substrates using the bonding device according to an embodiment of the present invention is described below with reference to FIGS. 15A and 15B. FIG. 15A is a flowchart of a substrate bonding process performed by the first substrate-bonding device; and FIG. 15B is a flowchart of a substrate bonding process performed by the second substrate-bonding device. Firstly, a pattern used for detecting positional deviations is formed together with a light emission element, a light receiving element, and a circuit pattern on the stripper layer of the wafer 72 made of a III-V group substrate. It is allowable to use a part of the circuit pattern as the pattern used for detecting positional deviation.

The wafer 72 is 3 inches in the diameter and 400 μm in the thickness. A part of the element layer that falls on a periphery to which no pattern is to be transferred is removed using etching. The wafer 71, a wafer to be bonded with the wafer 72, is made of glass and 12 inches in the diameter and 400 μm in the thickness. A base pattern is formed on a stripper layer, a SiO₂ film is formed on the stripper layer, and an outermost surface is then polished. The base pattern includes a pattern used for detecting positional deviation in addition to an optical waveguide pattern. It is allowable to use a part of the optical waveguide pattern as the pattern used for detecting positional deviations.

The prepared wafer 71 is subjected to a rough adjustment (pre-alignment) of the position in the horizontal direction and the rotation in the horizontal plane by a pre-alignment mechanism (not shown), and then attached to the press-contact unit 79 through vacuum contact (step S701). Then, a fine adjustment in the position in the horizontal direction and the rotation in the rotating direction is performed by using a reference mark on the wafer stage 73 (step S701). The wafer 72 is also subjected to the rough adjustment (pre-alignment) in the position in the horizontal direction and the rotation in the horizontal plane with a notch defined as a reference by the pre-alignment mechanism (not shown) in a similar manner as the wafer 71 is subjected to (step S702), and then, fixed to the wafer chuck 80 on the wafer stage 73. The wafer 72 is fixed to the wafer chuck 10 by utilizing the portion of the periphery of the wafer 72 where the pattern is not formed.

Subsequently, the precision alignment mark on the wafer 72 is detected, whereby the fine adjustment of the position of the wafer 72 in the horizontal direction and the direction of rotation is performed (step S702). By detecting the precision alignment mark on the wafer 71, the positional coordinates of the base pattern on the wafer 71 is recorded as a value to the wafer stage coordinates at this stage to form a map centered at the shot. This map is used as the value of the center coordinates upon the transfer. Because the wafer 71 is made of glass, a widely-used visible light can be used as an alignment light. The alignment light is transmitted through the wafer 71, and then reaches the wafer 72 to detect the alignment mark formed on the wafer 72.

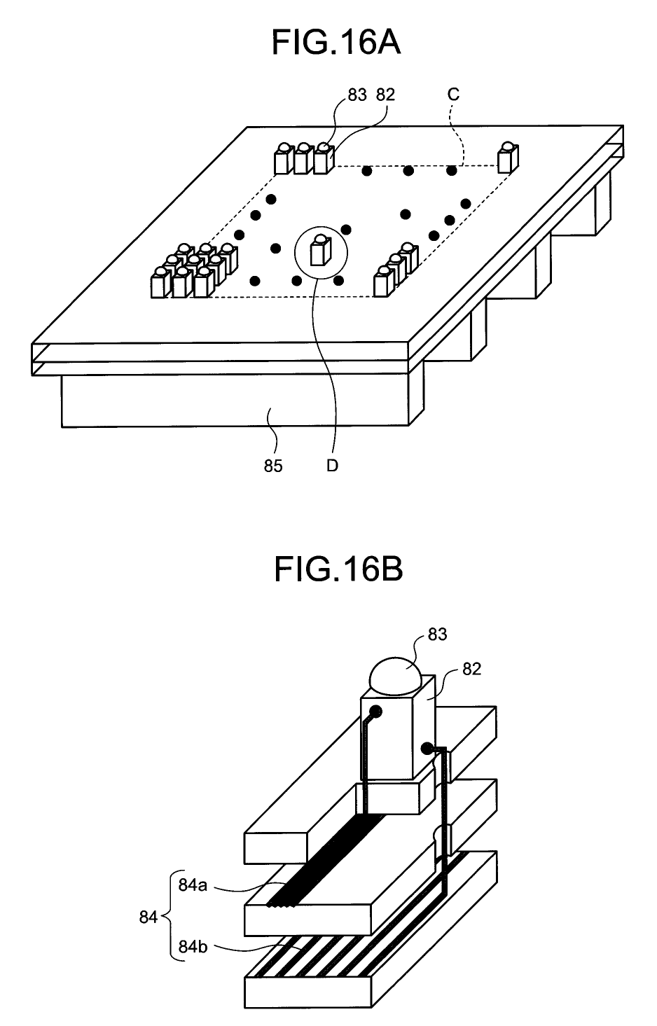

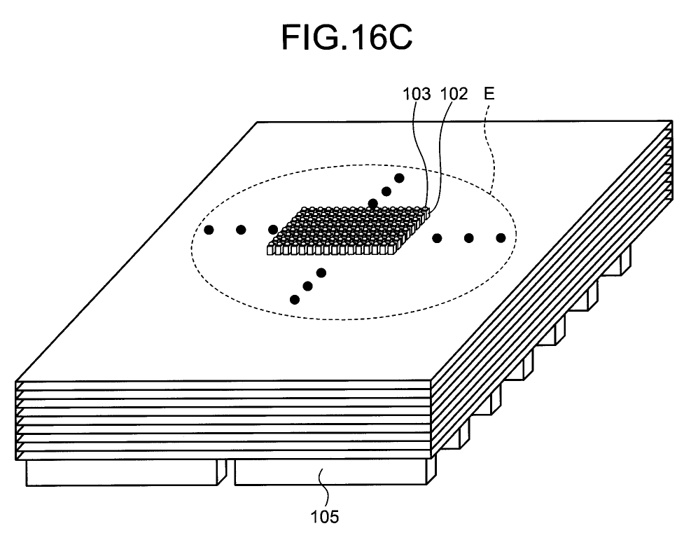

The height adjusting unit 74 includes piezoelectric elements 82 made of PZT arranged in a lattice shaped at an interval of 1 mm. A total number of 2809 (53×53) piezoelectric elements are stored in the storing unit 81, covering an area (50 mm×50 mm) of the wafer 71 on which elements are formed. As shown in FIG. 16A, the piezoelectric elements 82 that are a major portion of the height adjusting unit 74 are arranged in an area C indicated by a dotted square each side being 52 mm. Each of the piezoelectric elements 82 is adhered with a wafer contact chip 83 made of a hard fluororesin. FIG. 16A is a perspective diagram of the height adjusting unit 74. The hard fluororesin hardly becomes a contaminant source of metals or the like and has low dusting characteristics. Therefore, the hard fluororesin is suitable for a material contacting with the wafer.

FIG. 16B is an enlarged diagram of an area D shown in FIG. 16A. As shown in FIG. 16B, each of the piezoelectric elements 82 includes two contact terminals, one for connecting to a common electric potential line (grounded electric potential line) 84a and the other for connecting to a control line 84b. The common electric potential line 84a and the control line 84b are formed by a two-layered printed circuit board 84. To suppress an effect of noise, the common electric potential line 84a is formed on a layer closer to the piezoelectric elements 82. A minimum wire pitch between the control lines 84b on the printed circuit board 84 is 40 μm. The control line 84b is connected to a wire connector 85 on a surface opposite to the surface on which the piezoelectric elements 82 are formed.

A movable range of each of the piezoelectric elements 82 is ±1 μm. In response to the signal received from the control unit 75, a predetermined voltage is applied to each of the piezoelectric elements 82 so that a desired height distribution is formed. More particularly, a memory for storing a voltage to be applied to each of the control lines 84b is provided on the surface on which the wire connector 85 is formed. The digital signal received from the control unit 75 is directly written onto the memory. A total capacity of the memory is 64 kilobits. A 12-bit digital-analog convertor (DA conversion amplifier) generates the voltage to be applied to each of the control lines 84b by referring to values stored in the memory.

The above configuration makes it possible to remarkably reduce the number of wires that connect between the wire connector 85 and the control unit 75. In a case of another configuration in which the control unit 75 generates all voltage to be applied to each of the piezoelectric elements 82 and applies the voltage via wires, the number of required wires is a value one larger than the total number of the piezoelectric elements. In the case that the voltage is generated on the printed circuit board, because wires are not required except an address line, a data line, and a power line that are used for writing onto the memory, it is possible to reduce the number of the required wires to several tens. The entire part of the storing unit 81 can move upward or downward, which allows the height adjusting unit 74 to keep away from the wafer 72 when the bonding process is not performed, for example, when the wafer 72 moves together with the wafer stage 73 to a next area to be bonded.

When the wafer 71 and the wafer 72 are placed in the above-mentioned predetermined state ready for the bonding, the wafer stage 73 is moved to such a position that the center coordinates of a target bond area in the wafer 71 matches with the center coordinates of the wafer 72. Subsequently, the storing unit 81 moves to such a position that the height adjusting unit 74 is close to a lower surface of the wafer 72 (i.e., surface opposite to the bond surface with which the wafer 71 is bonded). The press-contact unit 79 performs the first-stage operation so that the wafer 71 is in about 5 μm away from the wafer 72. After that, fine adjustment for matching the center coordinates of the target bond area in the wafer 71 with the center coordinates of the wafer 72 is performed through a fine motion of the wafer stage 73 as precise alignment between the wafers (step S703).

In this state, the positional-deviation distribution measuring unit 76 optically measures the positional deviation amount between the positional deviation detecting pattern on the wafer 71 and the positional deviation detecting pattern on the wafer 72, and calculates the positional deviation distribution from the positional deviation amount (step S704). Assuming that a result of the measurement is defined as u(x, y) in which u is a two-dimensional vector amount, the positional deviation u(x, y) can be cancelled according to the above-mentioned principle with h=2/(tW+tM)∫udl that is obtained from the u(x, y) using a line integral. Since the u(x, y) is actually not a continuous value but a discrete value, the integration is approximated with the sum, and the map h1 of the approximate value of h is obtained by the operation unit 77.

The position of the positional deviation detecting pattern does not always agree with the lattice position of the height adjusting unit 74. Therefore, the operation unit 77 makes an approximate polynomial to the map h1 of the approximate value to obtain each coefficient of the polynomial by the least squares method. The obtained coefficient of the polynomial is sent to the control unit 75 as data.

The control unit 75 obtains the height distribution information for correcting the positional deviation distribution by using the coefficient of the polynomial received from the operation unit 77, and calculates the correction height distribution information h2 that should be given to each lattice point of the height adjusting unit 74 (step S705). The control unit 75 converts the correction height distribution information h2 into the voltage to be applied to each of the piezoelectric elements 82 of the height adjusting unit 74, and applies the voltage to the piezoelectric elements 82 for adjusting the height distribution in the plane at the transfer position (step S706).

After that, the press-contact unit 79 performs the second-stage operation of pressing the wafer 71 against the wafer 72. The storing unit 81 causes the height adjusting unit 74 to come in contact with the lower surface of the wafer 72. The vacuum contact at the bonded portion of the wafer 71 is released, simultaneously. As a result, the wafer 72 is directly bonded with the predetermined position on the wafer 71 in a state of the positional deviation is cancelled (step S707). It is allowable to press the wafer 71 against the wafer 72 after the height adjusting unit 74 contacts with the lower surface of the wafer 72.

After the wafer 71 and the wafer 72 are bonded with each other, the bonded state is checked using a visible light irradiated from an upper surface of the wafer 71 (surface opposite to the bond surface that is bonded with the wafer 72). When it is determined that the direct bond is formed (zero contact state), the wafer chuck 80 is released, the storing unit 81 moves downward so that the height adjusting unit 74 is in a position not contacting with the wafer 72, and the press-contact unit 79 moves about 5 μm upward.

After that, the substrate stripper-light irradiating unit 78 irradiates an infrared pulsed light from the lower surface of the wafer 72 (step S708) to separate the stripper layer of the wafer 72 from the element area of the wafer 72. In other words, the wafer 71 is separated from the base substrate of the wafer 72 (step S709). The press-contact unit 79 holds the wafer 71 through vacuum contact again. The separated base substrate of the wafer 72 is held by the wafer chuck 80 and is conveyed by the wafer stage 73 out to an unload port (not shown).

Thereafter, the control unit 75 determines whether a next position, i.e., a portion to be bonded with the wafer 72 is present on the wafer 71 (step S710). When the control unit 75 determines that the next bond position is present (Yes at step S710), the process control returns to step S702, loads a next one of the wafer 72, and repeats steps S702 to S709. When the control unit 75 determines that the next bond position is not present (No at step S710), i.e., all of bond positions on the wafer 71 has been subjected to the bonding process, the wafer 71 is unloaded from the press-contact unit 79 (step S711), and the bonding process of producing a next one of the wafer 71 starts.

According to the above processes, it is possible to obtain the bonded wafer 91 including the light emission element, the light receiving element, the circuit pattern, and the optical waveguide pattern but not having the extremely small positional deviation distribution that is obtained by correcting deformation on a portion of the wafer. Another optical-waveguide layer can be formed on the bonded wafer 91 as required.

A wafer in which electric wires for a typical complementary metal oxide semiconductor (CMOS) circuit are formed on a silicon substrate having a 12-inch diameter and a 720-μm thickness is prepared as the wafer 92. Because the wafer 92 is subjected to a typical CMOS-circuit fabrication process, the wafer 92 has an ordinal position alignment mark. In addition, a pattern used for detecting positional deviation is formed on the wafer 92. It is allowable to use a part of the circuit pattern as the pattern used for detecting positional deviation.

A SiO₂ film is formed as the uppermost layer of the wafer 92. After the SiO₂ film is formed, the surface of the wafer 92 is polished ready for the direct bonding. The surface of the bonded wafer 91 that includes the light emission element, the light receiving element, the circuit pattern, and the optical waveguide pattern is polished ready for the direct bonding. The bonded wafer 91 already has the pattern used for detecting positional deviation that is used in the above bonding process. The pattern is used again in the current bonding process.

The prepared wafer 91 is subjected to a rough adjustment (pre-alignment) of the position in the horizontal direction and the rotation in the horizontal plane by a pre-alignment mechanism (not shown), and then attached to the press-contact unit 99 through vacuum contact (step s801). Then, a fine adjustment in the position in the horizontal direction and the rotation in the rotating direction is performed by using a reference mark on the wafer stage 93 (step S801).

The wafer 92 is also subjected to the rough adjustment (pre-alignment) in the position in the horizontal direction and the rotation in the horizontal plane with a notch defined as a reference by the pre-alignment mechanism (not shown) in a similar manner as the wafer 91 is subjected to (step S802), and then, fixed to the wafer chuck 100 on the wafer stage 93. The wafer 92 is fixed to the wafer chuck 100 by utilizing the portion of the periphery of the wafer 92 where the pattern is not formed.

Subsequently, the precision alignment mark on the wafer 92 is detected, whereby the fine adjustment of the position of the wafer 92 in the horizontal direction and the direction of rotation is performed (step S802). Because the wafer 91 is made of glass, a widely-used visible light can be used as an alignment light. The alignment light is transmitted through the wafer 91, and then reaches the wafer 92 to detect the alignment mark formed on the wafer 92.

The height adjusting unit 94 includes piezoelectric elements 102 made of PZT arranged in a lattice shaped at an interval of 1 mm. A total number of 68,000 piezoelectric elements are stored in the storing unit 101, covering areas of the wafers 91 and 92 on which elements are formed. As shown in FIG. 16C, the piezoelectric elements 102 that are a major portion of the height adjusting unit 94 are arranged in an area E indicated by a dotted circle having a 284-mmφ diameter. Each of the piezoelectric elements 102 is adhered with a wafer contact chip 103 made of a hard fluororesin. FIG. 16C is a perspective diagram of the height adjusting unit 94. The hard fluorocarbon resin hardly becomes a contaminant source of metals or the like and has low dusting characteristics. Therefore, the hard fluororesin is suitable for a material contacting with the wafer.

Each of the piezoelectric elements 102 includes two contact terminals, one for connecting to a common electric potential line (grounded electric potential line) and the other for connecting to a control line in a manner similar to the piezoelectric elements 82 shown in FIG. 16B. The common electric potential line and the control line are formed by a nine-layered printed circuit board. To suppress an effect of noise, the common electric potential line is formed on a layer closest to the piezoelectric elements 102. A minimum wire pitch between the control lines on the printed circuit board is 50 μm. The control line is connected to a wire connector 105 on a surface opposite to the surface on which the piezoelectric elements 102 are formed.

A movable range of each of the piezoelectric elements 102 is ±1 μm. In response to the signal received from the control unit 95, a predetermined voltage is applied to each of the piezoelectric elements 102 so that a desired height distribution is formed. More particularly, a memory for storing a voltage to be applied to each of the control lines is provided on the surface on which the wire connector 105 is formed. The digital signal received from the control unit 95 is directly written onto the memory. A total capacity of the memory is 1 megabit. A 12-hit digital-analog convertor (DA conversion amplifier) generates the voltage to be applied to each of the control lines by referring to values stored in the memory.

The above configuration makes it possible to remarkably reduce the number of wires that connect between the wire connector 105 and the control unit 95. In a case of another configuration in which the control unit 95 generates all voltage to be applied to each of the piezoelectric elements 102 and applies the voltage via wires, the number of required wires is a value one larger than the total number of the piezoelectric elements. In the case that the voltage is generated on the printed circuit board, because wires are not required except an address line, a data line, and a power line that are used for writing onto the memory, it is possible to reduce the number of the required wires to several tens. The entire part of the storing unit 101 can move upward or downward, which allows the height adjusting unit 94 to keep away from the wafer 92 when the bonding process is not performed, for example, when the wafer 92 moves together with the wafer stage 93 to an area to be bonded.

When the wafer 91 and the wafer 92 are placed in the above-mentioned predetermined state ready for the bonding, the wafer stage 93 is moved to such a position that the center coordinates of a target bond area in the wafer 91 matches with the center coordinates of the wafer 92. Subsequently, the storing unit 101 moves to such a position that the height adjusting unit 94 is close to a lower surface of the wafer 92 (i.e., the surface opposite to the bond surface with which the wafer 91 is bonded). The press-contact unit 99 performs the first-stage operation so that the wafer 91 is in about 5 μm away from the wafer 92. After that, fine adjustment for matching the center coordinates of the target bond area in the wafer 91 with the center coordinates of the wafer 92 is performed through a fine motion of the wafer stage 93 as precise alignment between the wafers (step S803).

The positional-deviation distribution measuring unit 96 optically measures the positional deviation amount between the positional deviation detecting pattern on the wafer 91 and the positional deviation detecting pattern on the wafer 92, and calculates the positional deviation distribution from the positional deviation amount (step S804). Assuming that a result of the measurement is defined as u(x, y) in which u is a two-dimensional vector amount, the positional deviation u(x, y) can be cancelled according to the above-mentioned principle with h=2/(tW+tM)∫udl that is obtained from the u(x, y) using a line integral. Since the u(x, y) is actually not a continuous value but a discrete value, the integration is approximated with the sum, and the map h1 of the approximate value of h is obtained by the operation unit 97.

The position of the positional deviation detecting pattern does not always agree with the lattice position of the height adjusting unit 94. Therefore, the operation unit 97 makes an approximate polynomial to the map h1 of the approximate value to obtain each coefficient of the polynomial by the least squares method. The obtained coefficient of the polynomial is sent to the control unit 95 as data.

The control unit 95 obtains the height distribution information for correcting the positional deviation distribution by using the coefficient of the polynomial received from the operation unit 97, and calculates the correction height distribution information h2 that should be given to each lattice point of the height adjusting unit 94 (step S805). The control unit 95 converts the correction height distribution information h2 into the voltage to be applied to each of the piezoelectric elements 102 of the height adjusting unit 94, and applies the voltage to the piezoelectric elements 102 for adjusting the height distribution in the plane at the transfer position (step S806).

After that, the press-contact unit 99 performs the second-stage operation of pressing the wafer 91 against the wafer 92. The storing unit 101 causes the height adjusting unit 94 to come in contact with the lower surface of the wafer 92. The vacuum contact at the bonded portion of the wafer 91 is released, simultaneously. As a result, the wafer 92 is directly bonded with the predetermined position on the wafer 91 in a state of the positional deviation is cancelled (step S807). It is allowable to press the wafer 91 against the wafer 92 after the height adjusting unit 94 contacts with the lower surface of the wafer 92.

After the wafer 91 and the wafer 92 are bonded with each other, the bonded state is checked using a visible light irradiated from an upper surface of the wafer 91 (surface opposite to the bond surface that is bonded with the wafer 92). When it is determined that the direct bond is formed (zero contact state), the wafer chuck 100 is released, the storing unit 101 moves downward so that the height adjusting unit 94 is in a position not contacting with the wafer 92, and the press-contact unit 99 moves about 5 μm upward.

After that, the substrate stripper-light irradiating unit 98 irradiates an infrared pulsed light from the upper surface of the wafer 91 (step S808) to separate the stripper layer of the wafer 91 from the element area of the wafer 91. In other words, the wafer 92 is separated from the base substrate of the wafer 91 (step S809). The press-contact unit 99 holds the separated base substrate of the wafer 91 through vacuum contact again. Then the separated base substrate of the wafer 91 is conveyed out to an unload port (not shown).

The wafer 92 after the bonding process is held by the wafer chuck 100 again, and conveyed to another unloads port (not shown) by the wafer stage 93 (step S810). After that, a next one of wafers is subjected to the above process. According to the above process, it is possible to obtain a bonded substrate that is made from the wafer 91 including the light emission element, the light receiving element, the circuit pattern, and the optical waveguide pattern and the silicon CMOS circuit substrate 92 but has the extremely small positional deviation distribution that is obtained by correcting deformation in the in-plane direction on a portion of the substrate. Another electric wiring layer can be formed on the bonded wafer as appropriate.

According to the seventh embodiment, it is possible to correct deformation in the in-plane direction on a portion of the substrate thereby obtaining a high-quality bonded substrate having a remarkably-enhanced positional-alignment precision between substrates 151 and 152 and an extremely small positional deviation distribution.

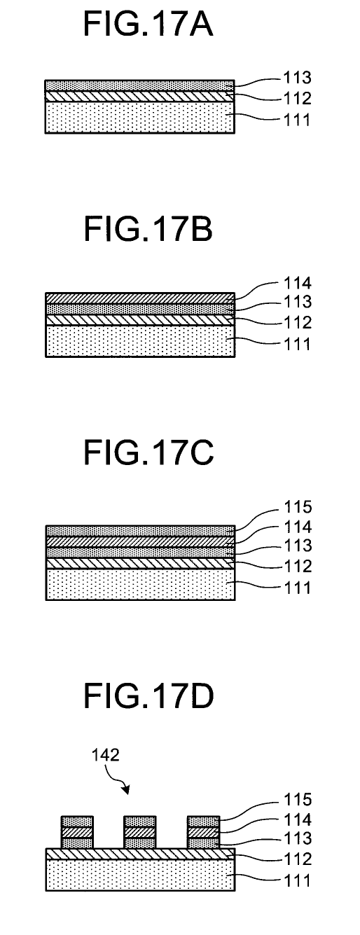

A method of manufacturing a semiconductor device according to an embodiment of the present invention using the first substrate-bonding device and the second substrate-bonding device according to the seventh embodiment is described with reference to FIGS. 17A to 19D in an eighth embodiment of the present invention. FIGS. 17A to 19D are cross-sectional diagrams for explaining a method of manufacturing a semiconductor device according to the eighth embodiment.

Firstly, as shown in FIG. 17A, a gallium arsenide (GaAs) substrate 111 having a 3-inch diameter is subjected to an indium (In)- and antimony (Sb)-ion implantation, and crystallinity recovery annealing to form a stripper layer 112 firstly and a buffer layer 113 secondly on a surface of the GaAs substrate 111. Those layers can be formed by a deposition method instead. As shown in FIG. 17B, an optical element layer 114 including a gallium indium nitride arsenide (GaInNAs) light emission layer and an indium gallium arsenide (InGaAs) light receiving layer is epitaxially grown on the buffer layer 113. A pulled-out wire section (not shown) is then formed.

As shown in FIG. 17C, a buffer layer 115 made of silicon dioxide (SiO₂) is formed on the optical element layer 114 using a sputtering method. An uppermost surface is then polished. After that, as shown in FIG. 17D, portions unnecessary as the optical element (i.e., a part of the buffer layer 113, a part of the optical element layer 114, and a part of the buffer layer 115) including a wafer peripheral are removed using a photolithography process and an etching method. A resultant substrate is referred to as a substrate 142.

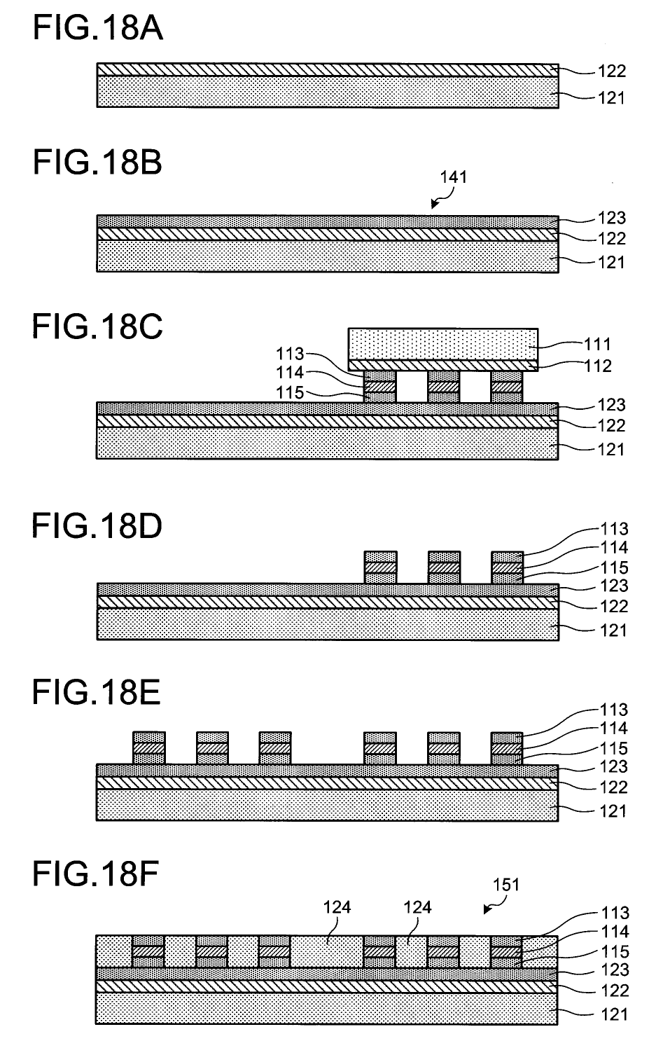

Then, as shown in FIG. 18A, a thin glass film containing chromium (Cr) is formed as a stripper layer 122 on a glass substrate 121 having a 12-inch diameter. As shown in FIG. 18B, an optical waveguide layer 123 that is made of silicon nitride (Si₁₋ₓNₓ) embedded into a SiO₂ film is formed on the stripper layer 122. The uppermost surface of the SiO₂ film is polished. A resultant substrate is referred to as a substrate 141.

Then, as shown in FIG. 18C, the substrate 142 shown in FIG. 17D is bonded with the substrate 141 using the first substrate-bonding device such that the substrate 142 in an upside-down state is placed on the substrate 141. As shown in FIG. 18D, the substrate stripper-light irradiating unit of the first substrate-bonding device irradiates, for example, an infrared pulsed light as the stripper light from a surface of the substrate 111 opposite to the bond surface thereby separating the substrate 111 from the stripper layer 112.

As shown in FIG. 18E, the substrate 142 is bonded again with another target area of the substrate 141 using the first substrate-bonding device. As shown in FIG. 18F, a SiO₂ film 124 is formed all over the substrate as shown in FIG. 18E using a plasma chemical vapor deposition (CVD) method using tetraethoxysilane (TEOS). A surface of the SiO₂ film 124 is then polished to be planarized. A resultant substrate is referred to as the substrate 151.

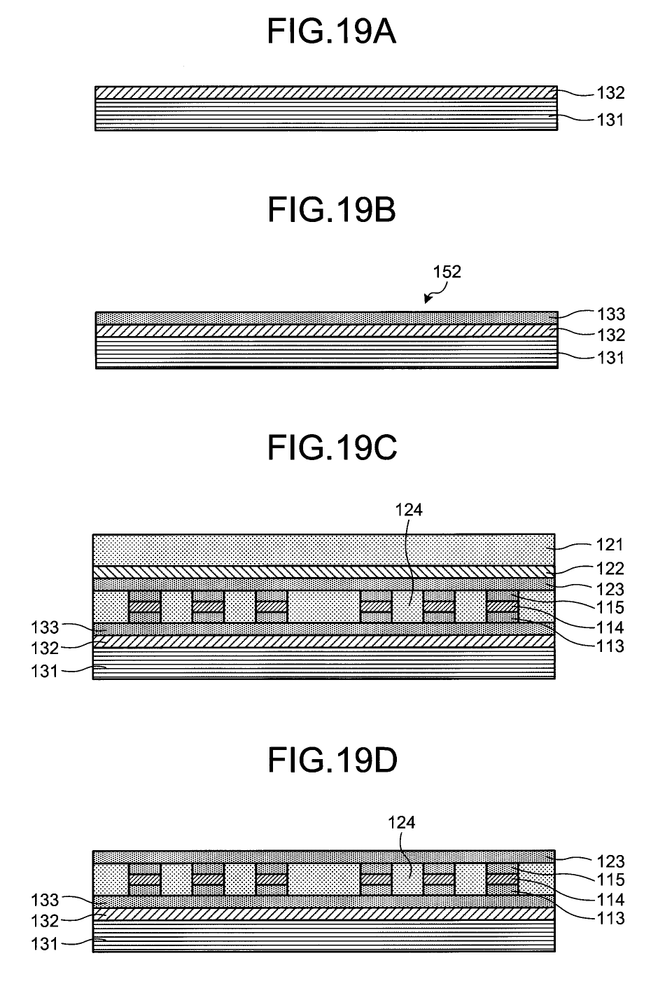

Then, as shown in FIG. 19A, a CMOS circuit layer 132 including an electric circuit wiring is formed on a silicon substrate 131 having a 12-inch diameter using a typical CMOS-circuit fabrication process. As shown in FIG. 19B, a SiO₂ film 133 is formed over the substrate using a plasma-CVD method using TEOS. The surface of the substrate is then polished to be planarized. A resultant substrate is referred to as the substrate 152.

Then, as shown in FIG. 19C, the substrate 152 shown in FIG. 18F is bonded with the substrate 151 using the second substrate-bonding device such that the substrate 151 in an upside-down state is placed on the substrate 152. As shown in FIG. 19D, the substrate stripper-light irradiating unit of the second substrate-bonding device irradiates the stripper light having a wavelength different from the stripper light emitted from the substrate stripper-light irradiating unit of the first substrate-bonding device from a surface of the substrate 121 opposite to the bond surface that is bonded with the substrate 152 thereby separating the substrate 121 from the stripper layer 122.

After that, though not shown in the drawings, the substrate 152 is subjected to a wiring layer fabrication process of connecting between elements on the optical element layer 114 and the circuit of the CMOS circuit layer 132. The substrate 152 is then subjected to a common semiconductor element fabrication process such as a final passivation process or a pad forming process. As a result, the optoelectronic semiconductor element is produced.

According to the above process, it is possible to correct deformation in the in-plane direction on a portion of the substrate thereby producing the high-quality optoelectronic semiconductor element having a remarkably-enhanced positional-alignment precision between the substrate 151 and the substrate 152 and an extremely small positional deviation distribution.

The present invention is not limited to the above embodiments. Although the direct bonding is used for bonding substrates, the bonded substrates can be subjected to a heating treatment for strengthening the bonding after the direct bonding. Moreover, it is allowable to use an anodic bonding, which is a treatment using electric field application and heating, as a bonding process. The piezoelectric elements can be made of another substance such as lanthanum-doped lead zirconate-lead titanate (PLZT) instead of PZT. The light emission element and the light receiving element are formed on the III-V group substrate according to the above embodiments. However, instead of providing the light emission element, it is allowable to provide an external light source and incorporate a light modulation element made of, for example, lithium niobate into the waveguide. Various modifications can be made to the present invention without departing from the scope of the present invention.

According to an embodiment of the present invention, it is possible to remarkably enhance the positional-alignment precision between a bond surface of a first substrate and a bond surface of a second substrate that are bonded with each other. This makes it possible to provide a method of manufacturing a semiconductor device and an apparatus for manufacturing the semiconductor device that can produce the precisely bonded semiconductor device having an extremely small positional deviation distribution between the first substrate and the second substrate.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method of manufacturing a semiconductor device, the method comprising:
performing positioning between a transfer position of a pattern forming surface of a transfer original plate on which a pattern to be transferred is formed and a transferred position of a transferred surface of a transferred substrate to which the pattern is to be transferred;
contacting the pattern forming surface with the transferred surface; and
partly correcting the positional deviation between the transfer position of the pattern forming surface and the transferred position of the transferred surface in the in-plane direction, after the positioning is performed.

2. The method according to claim 1, wherein the positional deviation is partly corrected by partly correcting the transferred position of the transferred surface in the in-plane direction, after the positioning is performed.

3. The method according to claim 2, wherein the distortion in the in-plane direction at the transferred position of the transferred surface is partly adjusted through the adjustment in part of the height of a part of the transferred position of the transferred surface, thereby correcting the partial positional deviation at the transferred position in the in-plane direction.

4. The method according to claim 3, wherein the adjustment in part of the height of the part of the transferred position is performed by pressing partly a surface of the transferred substrate which is opposed to the transferred surface.

5. The method according to claim 2, further comprising:
forming positional deviation distribution information by measuring the positional deviation between the transfer position of the pattern forming surface and the transferred position of the transferred surface in the in-plane direction, after the positioning is performed,
wherein the positional deviation is partly corrected by partly correcting the transferred position of the transferred surface in the in-plane direction based on the positional deviation distribution information.

6. The method according to claim 1, wherein the positional deviation is partly corrected by partly correcting the transfer position of the pattern forming surface in the in-plane direction, after the positioning is performed.

7. The method according to claim 6, further comprising:
forming positional deviation distribution information by measuring the positional deviation between the transfer position of the pattern forming surface and the transferred position of the transferred surface in the in-plane direction, after the positioning is performed,
wherein the positional deviation is partly corrected by partly correcting the transfer position of the pattern forming surface in the in-plane direction based on the positional deviation distribution information.

8. The method according to claim 6, wherein the positional deviation is partly corrected by partly correcting the transfer position on the pattern forming surface in the in-plane direction using the distortion generated by a material having a piezoelectric effect.

9. The method according to claim 1, wherein the pattern on the pattern forming surface is transferred onto the transferred surface by a lithography technique, after the positional deviation is partly corrected.

10. An apparatus for manufacturing a semiconductor, the apparatus comprising:
a press-contact unit that presses a pattern forming surface of a transfer original plate on which a pattern to be transferred is formed and a transferred surface of a transferred substrate to which a resist film is to be applied and the pattern is to be transferred, thereby bringing the pattern forming surface and the transferred surface into contact with each other;
a positioning unit that positions the transfer position of the pattern forming surface and the transferred position of the transferred surface;
a positional deviation correcting unit that partly corrects the positional deviation in the in-plane direction between the transfer position of the pattern forming surface and the transferred position of the transferred surface at the contact surface of the pattern forming surface and the transferred surface; and
a light source that irradiates light to expose the resist film on the transferred substrate.

11. The apparatus according to claim 10, wherein the positional deviation correcting unit partly corrects the positional deviation by partly correcting the transferred position of the transferred surface in the in-plane direction at the contact surface.

12. The apparatus according to claim 11, wherein the positional deviation correcting unit partly corrects the positional deviation by partly adjusting the height of a part of the transferred position at the contact surface.

13. The apparatus according to claim 12, wherein the positional deviation correcting unit presses partly a surface of the transferred substrate which is opposed to the transferred surface so as to partly adjust the height of the part of the transferred position.

14. The apparatus according to claim 10, wherein the positional deviation correcting unit partly corrects the positional deviation by partly correcting the transfer position of the pattern forming surface in the in-plane direction at the contact surface.

15. A method of manufacturing a semiconductor device including bonding of a first substrate and a second substrate, the method comprising:
holding a state of facing one surface of the first substrate and one surface of the second substrate and being close to each other;
aligning a position between the one surface of the first substrate and the one surface of the second substrate with respect to an in-plane direction;
measuring a distribution of positional deviations between the one surface of the first substrate and the one surface of the second substrate with respect to the in-plane direction after aligning the position;
bonding the one surface of the first substrate and the one surface of the second substrate by pressing from an opposite surface side of the first substrate; and
partly correcting the positional deviations between the first surface and the second surface with respect to the in-plane direction based on the distribution of positional deviations while pressing from the opposite surface side of the first substrate.

16. The method according to claim 15, wherein the correcting includes partly adjusting a height of a part of an opposite surface of the second substrate based on the distribution of positional deviations with respect to the in-plane direction thereby partly adjusting a deformation of the one surface of the second substrate with respect to the in-plane direction on a first surface of the second substrate and partly correcting the positional deviations of the one surface of the second substrate with respect to the in-plane direction.

17. The method according to claim 16, further comprising:
converting the distribution of the positional deviations between the one surface of the first substrate and the one surface of the second substrate with respect to the in-plane direction into a distribution of correction amounts of a height direction, wherein
the correcting includes partly adjusting a height of a part of the opposite surface of the second substrate based on the distribution of correction amounts of the height direction.

18. The method according to claim 16, wherein the second substrate is an element substrate on which an element layer is formed via a stripper layer, an element being formed on one surface of a base substrate of the element layer, and the method further comprising:
irradiating from the opposite surface of the second substrate a substrate stripper light for stripping the stripper layer to separate between the base substrate and the element layer, after correcting the positional deviations between the one surface of the first substrate and the one surface of the second substrate with respect to the in-plane direction.

19. The method according to claim 15, wherein
either one of the first substrate and the second substrate is a substrate including an element made of a IV group semiconductor including an electric wiring, and
other one of the first substrate and the second substrate is a substrate including an element made of a III-V group semiconductor including at least one of a light emission element and a light receiving element.

20. The method according to claim 15, wherein
the aligning of a position between the one surface of the first substrate and the one surface of the second substrate with respect to an in-plane direction is performed by using a position alignment light, and
a substrate through which the position alignment light is transmitted is used as the first substrate.

21. The method according to claim 15, further comprising bonding a third substrate with a fourth substrate through which a positional alignment light is transmitted thereby obtaining the first substrate.

22. The method according to claim 21, wherein
a plurality of the third substrates are bonded with the fourth substrate thereby obtaining the first substrate.

23. An apparatus for manufacturing a semiconductor device by bonding a first substrate and a second substrate, the apparatus comprising:
a holding unit that holds a state of facing one surface of the first substrate and one surface of the second substrate and being close to each other;
an aligning unit that aligns a position between the one surface of the first substrate and the one surface of the second substrate with respect to an in-plane direction while facing the one surface of the first substrate and the one surface of the second substrate;
a positional-deviation distribution measuring unit that measures a distribution of positional deviations between the one surface of the first substrate and the one surface of the second substrate with respect to the in-plane direction after aligning the position;
a press-contact unit that bonds the one surface of the first substrate and the one surface of the second substrate by pressing from the opposite surface side of the first substrate; and
a correcting unit that partly corrects the positional deviations between the one surface of the first substrate and the one surface of the second substrate with respect to the in-plane direction based on the distribution of positional deviations, while pressing from the opposite surface side of the first substrate by the press-contact unit.

24. The apparatus according to claim 23, wherein the correcting unit partly adjusts a height of a part of the opposite surface of the second substrate based on the distribution of positional deviations with respect to the in-plane direction thereby partly adjusting a deformation of the one surface of the second substrate with respect to the in-plane direction and partly correcting the positional deviations of the one surface of the second substrate with respect to the in-plane direction.

25. The apparatus according to claim 23, wherein the second substrate is an element substrate on which an element layer is formed via a stripper layer, an element being formed on one surface of a base substrate of the element layer, and the apparatus further comprising:
a substrate stripper-light irradiating unit that irradiates from the opposite surface of the second substrate a substrate stripper light for stripping the stripper layer to separate between the base substrate and the element layer, after the correcting unit corrects the positional deviations between the one surface of the first substrate and the one surface of the second substrate with respect to the in-plane direction.
